(19) United States
(12) Patent Application Publication
(10) Pub. No.: US 2022/0121102 A1
(43) Pub. Date: Apr. 21, 2022

(54) REFLECTIVE MASK BLANK, REFLECTIVE MASK, METHOD FOR PRODUCING SAME, AND METHOD FOR PRODUCING SEMICONDUCTOR DEVICE

(71) Applicant: HOYA CORPORATION, Tokyo (JP)

(72) Inventors: Tsutomu SHOKI, Tokyo (JP); Yohei IKEBE, Tokyo (JP)

(73) Assignee: HOYA CORPORATION, Tokyo (JP)

(21) Appl. No.: 17/431,700

(22) PCT Filed: Feb. 21, 2020
(86) PCT No.: PCT/JP2020/007002

§ 371 Date: Aug. 17, 2021

(30) Foreign Application Priority Data
Feb. 28, 2019 (JP) 2019-035300

(51) Int. Cl. G03F 1/24; H01L 21/033; G03F 1/58

(52) U.S. Cl. CPC G03F 1/24; G03F 1/58; H01L 21/0332; H01L 21/0337

(57) ABSTRACT

Provided is a reflective mask blank that enables to further reduce the shadowing effect of a reflective mask and form a fine and highly accurate absorber pattern.

The reflective mask blank comprising a multilayer reflective film, an absorber film, and an etching mask film disposed on a substrate in this order, wherein the absorber film comprises a buffer layer and an absorption layer provided on the buffer layer, the buffer layer comprises a material comprising tantalum (Ta) or silicon (Si) and a film thickness of the buffer layer is 0.5 nm or more and 25 nm or less, the absorption layer comprises a material comprising chromium (Cr) and an extinction coefficient of the absorption layer with respect to EUV light is higher than the extinction coefficient of the buffer layer with respect to the EUV light, and the etching mask film comprises a material comprising tantalum (Ta) or silicon (Si) and a film thickness of the etching mask film is 0.5 nm or more and 14 nm or less.

### CROSS-REFERENCE TO RELATED APPLICATIONS

This application is the National Stage of International Application No. PCT/JP2020/007002, filed Feb. 21, 2020, which claims priority to Japanese Patent Application No. 2019-035300, filed Feb. 28, 2019, and the contents of which is incorporated by reference.

### TECHNICAL FIELD

The present disclosure relates to a reflective mask blank that is an original plate for manufacturing an exposure mask used for manufacturing a semiconductor device or the like, a reflective mask, a method of manufacturing the same, and a method of manufacturing a semiconductor device.

### BACKGROUND ART

Types of light sources of exposure apparatuses in manufacturing semiconductor devices have been evolving while wavelengths thereof have been shortened gradually like a g-line having a wavelength of 436 nm, an i-line having a wavelength of 365 nm, a KrF laser having a wavelength of 248 nm, and an ArF laser having a wavelength of 193 nm. In order to achieve further finer pattern transfer, extreme ultra violet (EUV) lithography using EUV having a wavelength in the vicinity of 13.5 nm has been developed. A reflective mask is used in EUV lithography, because there are few materials transparent to EUV light. The reflective mask has a multilayer reflective film for reflecting exposure light on a low thermal expansion substrate. The reflective mask has, as a basic structure, a mask structure in which a desired pattern for transfer is formed on a protective film for protecting the multilayer reflective film. In addition, typical examples of the structure of the pattern for transfer include a binary-type reflection mask and a phase shift-type reflection mask (a half-tone phase shift-type reflection mask). The transfer pattern of the binary-type reflection mask includes a relatively thick absorber pattern that sufficiently absorbs EUV light. The transfer pattern of the phase shift-type reflection mask includes a relatively thin absorber pattern that reduces EUV light by light absorption and generates reflected light having a phase substantially inverted (a phase inverted by approximately 180°) with respect to reflected light from the multilayer reflective film. As with a transmissive optical phase shift mask, the phase shift-type reflection mask (half-tone phase shift-type reflection mask) can obtain high contrast of transferred optical image by a phase shift effect, thereby providing an effect of improving resolution. In addition, since the film thickness of the absorber pattern (the phase shift pattern) of the phase shift-type reflection mask is thin, a fine and highly accurate phase shift pattern can be formed.

In EUV lithography, a projection optical system including a large number of reflecting mirrors is used due to light transmittance. Since, EUV light obliquely incidents to the reflective mask, these reflecting mirrors not to block projection light (exposure light). At present, an incident angle is typically 6° with respect to a vertical plane of a reflection mask substrate. Along with the improvement of a numerical aperture (NA) of the projection optical system, studies are being conducted toward making the incident angle about 8° that is a more oblique incident angle.

In EUV lithography, since the exposure light is obliquely incident, there is an inherent problem called a shadowing effect. The shadowing effect is a phenomenon in which exposure light is obliquely incident on an absorber pattern having a three-dimensional structure, whereby a shadow is formed and a dimension and position of a transferred and formed pattern change. The three-dimensional structure of the absorber pattern serves as a wall to form a shadow on a shade side, and the dimension and position of the transferred and formed pattern change. For example, a difference occurs in a dimension and position of a transfer pattern between both cases, one of the cases that the orientation of the absorber pattern to be arranged is parallel to a direction of obliquely incident light and the other case is that the orientation of the absorber pattern to be arranged is perpendicular to the direction of the obliquely incident light, thereby decreasing transfer accuracy.

Patent Documents 1 and 2 disclose techniques related to such a reflective mask for EUV lithography and a mask blank for manufacturing the same. Patent Document 1 states that a reflective mask that has a reduced shadowing effect, is capable of phase shift exposure, and has sufficient shading frame performance is provided. Conventionally, the film thickness of the phase shift pattern is made relatively thin as compared with the case of the binary-type reflection mask, by using the phase shift-type reflection mask as the reflective mask for EUV lithography, whereby a decrease in the transfer accuracy due to the shadowing effect is reduced.

Patent Document 2 discloses reflective mask blanks including an absorber layer that has a stack in which at least an uppermost layer and lower layers that is other than the uppermost layer are included.

### PRIOR ART DOCUMENTS

### Patent Documents

Patent Document 1: JP 2009-212220 A

Patent Document 2: JP 2004-39884 A

### Disclosure of Invention

The finer the pattern is and the more the accuracy of the pattern dimension and pattern position is improved, the electrical characteristic performance of the semiconductor device is increased, the degree of integration becomes higher, and a chip size can be reduced. Therefore, EUV lithography requires an even higher level of high-precision, fine-dimension pattern transfer performance than in the prior art. At present, high-precision pattern formation is required for half pitch 16 nm (hp 16 nm) generation. In response to such a requirement, a further reduction in film thickness is required in order to reduce the shadowing effect. In particular, in the case of EUV exposure, the film thickness of the absorber film (the phase shift film) is required to be less than 60 nm and preferably 50 nm or less.

As disclosed in Patent Documents 1 and 2, Ta has been conventionally used as a material for forming the absorber film (phase shift film) of the reflective mask blank. However, the refractive index n of Ta in EUV light (for example, with a wavelength of 13.5 nm) is approximately 0.943. Therefore, even if a phase shift effect of Ta is used, the film thickness of an absorber film (phase shift film) formed of Ta alone is thinned to the lowest limit of 60 nm. To make the film thickness thinner, for example, a metal material having a high extinction coefficient k (high absorption effect) can be used as an absorber film of a binary-type reflective mask blank. Examples of metal materials having a high extinction coefficient k at a wavelength of 13.5 nm include cobalt (Co) and nickel (Ni). However, it is known that Co thin films and Ni thin films are relatively difficult to etch during patterning.

It is also conceivable to use an absorber film made of a material containing Cr (a Cr-based material), which has a higher k than a Ta-based material. However, since a Cr-based material is etched with a mixed gas of a chlorine gas and an oxygen gas, it is necessary to increase the film thickness of the resist film in order to form a pattern of the absorber film made of a Cr-based material. As a result, in a case an absorber film made of a Cr-based material is used, a problem of failing to form a fine pattern is arisen because of a thicker resist film.

In view of the points described above, it is an aspect of the present disclosure to provide a reflective mask blank that enables to further reduce the shadowing effect of a reflective mask and form a fine and highly accurate absorber pattern, a reflective mask manufactured with the reflective mask blank, and a method of manufacturing a semiconductor device. Another aspect of the present disclosure is to provide a reflective mask blank for manufacturing a reflective mask in which an absorber film has a reflectance of 2% or less in EUV light, a reflective mask manufactured with the reflective mask blank, and a method of manufacturing a semiconductor device.

In order to solve the above problems, the present disclosure has the following configurations.

(Configuration 1)

A configuration 1 of the present disclosure is a reflective mask blank including a multilayer reflective film, an absorber film, and an etching mask film that are disposed on a substrate in this order, in which

the absorber film comprises a buffer layer and an absorption layer provided on the buffer layer,

the buffer layer comprises a material containing tantalum (Ta) or silicon (Si), and a film thickness of the buffer layer is 0.5 nm or more and 25 nm or less,

the absorption layer comprises a material comprising chromium (Cr) and extinction coefficient of the absorption layer with respect to EUV light is higher than the extinction coefficient of the buffer layer with respect to the EUV light, and

the etching mask film comprises a material comprising tantalum (Ta) or silicon (Si) and a film thickness of the buffer layer is 0.5 nm or more and 14 nm or less.

(Configuration 2)

A configuration 2 of the present disclosure is the reflective mask blank of the configuration 1, in which the material of the buffer layer comprises tantalum (Ta) and one or more elements selected from oxygen (O), nitrogen (N), and boron (B).

(Configuration 3)

A configuration 3 of the present disclosure is the reflective mask blank of the configuration 1 or 2, in which the material of the buffer layer comprises tantalum (Ta) and at least one element selected from nitrogen (N) and boron (B), and the film thickness of the buffer layer is 25 nm or less.

(Configuration 4)

A configuration 4 of the present disclosure is the reflective mask blank of the configuration 1 or 2, in which the material of the buffer layer comprises tantalum (Ta) and oxygen (O), and the film thickness of the buffer layer is 15 nm or less.

(Configuration 5)

A configuration 5 of the present disclosure is the reflective mask blank of any one of the configurations 1 to 4, in which the material of the absorption layer comprises chromium (Cr) and at least one element selected from nitrogen (N) and carbon (C).

(Configuration 6)

A configuration 6 of the present disclosure is the reflective mask blank of any one of the configurations 1 to 5, in which the material of the absorption layer comprises chromium (Cr) and nitrogen (N), and the film thickness of the absorption layer is 25 nm or more and less than 60 nm.

(Configuration 7)

A configuration 7 of the present disclosure is the reflective mask blank of any one of the configurations 1 to 6, in which the material of the etching mask film comprises tantalum (Ta) and one or more elements selected from oxygen (O), nitrogen (N), and boron (B).

(Configuration 8)

A configuration 8 of the present disclosure is the reflective mask blank of any one of the configurations 1 to 6, in which the material of the etching mask film comprises tantalum (Ta) and one or more elements selected from nitrogen (N) and boron (B) and does not contain oxygen (O).

(Configuration 9)

A configuration 9 of the present disclosure is the reflective mask blank of any one of the configurations 1 to 6, in which the material of the etching mask film comprises silicon (Si) and at least one element selected from oxygen (O) and nitrogen (N).

(Configuration 10)

A configuration 10 of the present disclosure is the reflective mask blank of the configuration 9, in which the material of the buffer layer comprises silicon (Si) and at least one element selected from oxygen (O) and nitrogen (N).

(Configuration 11)

A configuration 11 of the present disclosure is the reflective mask blank of any one of the configurations 1 to 10, in which a protective film is provided between the multilayer reflective film and the absorber film.

(Configuration 12)

A configuration 12 of the present disclosure is the reflective mask blank of any one of the configurations 1 to 11, in which a resist film is provided on the etching mask film.

(Configuration 13)

A configuration 13 of the present disclosure is a reflective mask comprising an absorber pattern in which the absorber film in the reflective mask blank of any one of the configurations 1 to 12 is patterned.

(Configuration 14)

A configuration 14 of the present disclosure is a method of manufacturing a reflective mask, the method comprising: patterning the etching mask film of the reflective mask blank of any one of the configurations 1 to 12 with a dry etching gas comprising a fluorine-based gas; patterning the absorption layer with a drying etching gas comprising a chlorine-based gas and an oxygen gas; and patterning the buffer layer with a dry etching gas comprising a chlorine-based gas to form an absorber pattern.

(Configuration 15)

A configuration 15 of the present disclosure is a method of manufacturing a semiconductor device, the method including: setting the reflective mask of the configuration 13 in an exposure apparatus having an exposure light source that emits EUV light and transferring a transfer pattern to a resist film formed on a transferred substrate.

According to the present disclosure, a reflective mask blank that enables to further reduce the shadowing effect of a reflective mask and form a fine and highly accurate absorber pattern can be provided. In addition, according to the present disclosure, a reflective mask that enables to reduce the film thickness of an absorber film and reduce the shadowing effect with a fine and highly accurate absorber film formed thereon, and a method of manufacturing the reflective mask can be provided. Furthermore, according to the present disclosure, a semiconductor device having a fine and highly accurate transfer pattern can be manufactured.

In addition, according to the present disclosure, a reflective mask blank for manufacturing a reflective mask in which an absorber film has a reflectance of 2% or less in EUV light, a reflective mask manufactured with the reflective mask blank, and a method of manufacturing a semiconductor device can be provided.

### BRIEF DESCRIPTION OF DRAWINGS

FIG. 1 is a schematic cross-sectional diagram of a main part for describing a schematic configuration of a reflective mask blank of the present disclosure.

FIGS. 2(a) to 2(e) are step diagrams showing, in a schematic cross-sectional diagram of a main part, steps of manufacturing a reflective mask from the reflective mask blank.

FIG. 3 is a diagram showing a relationship between the film thickness D (=d1+d2, nm) and the EUV light reflectance (%) on a surface of an absorber film, where d1 is the film thickness of a CrN absorption layer, d2 is the film thickness of a TaBN buffer layer, and the thickness d2 of the buffer layer is varied in the range of 2 to 20 nm.

FIG. 4 is a diagram showing the EUV light reflectance (%) on a surface of an absorber film, where d1 is the film thickness of a CrN absorption layer, d2 is the film thickness of a TaBN buffer layer, the film thickness D (=d1+d2) of an absorber film is 47 nm, and the thickness d2 of the TaBN buffer layer is varied in the range of 0 to 47 nm.

FIG. 5 is a diagram showing a relationship between the film thickness D (=d1+d2, nm) of the absorber film and the EUV light reflectance (%) on a surface of an absorber film, where d1 is the film thickness of a CrN absorption layer, d2 is the film thickness of a TaBO buffer layer, and the thickness d2 of the buffer layer is varied in the range of 2 to 20 nm.

FIG. 6 is a diagram showing the EUV light reflectance (%) on a surface of an absorber film, where d1 is the film thickness of a CrN absorption layer, d2 is the film thickness of a TaBO buffer layer, the film thickness D (=d1+d2) of an absorber film is 47 nm, and the thickness d2 of the TaBO buffer layer is varied in the range of 0 to 47 nm.

FIG. 7 is a diagram showing a relationship between the film thickness D (=d1+d2) of an absorber film (absorption layer/buffer layer) and the EUV light reflectance (%) on a surface of the absorber film, which is obtained through simulation.

### DESCRIPTION OF EMBODIMENTS

Hereinafter, embodiments of the present disclosure will be specifically described with reference to the drawings. Note that each of the following embodiments is one mode for embodying the present disclosure and does not limit the present disclosure within the scope thereof. Note that in the drawings, the same or corresponding parts are denoted by the same reference signs, and description thereof may be simplified or omitted.

<Configuration of Reflective Mask Blank 100 and Method of Manufacturing the Same>

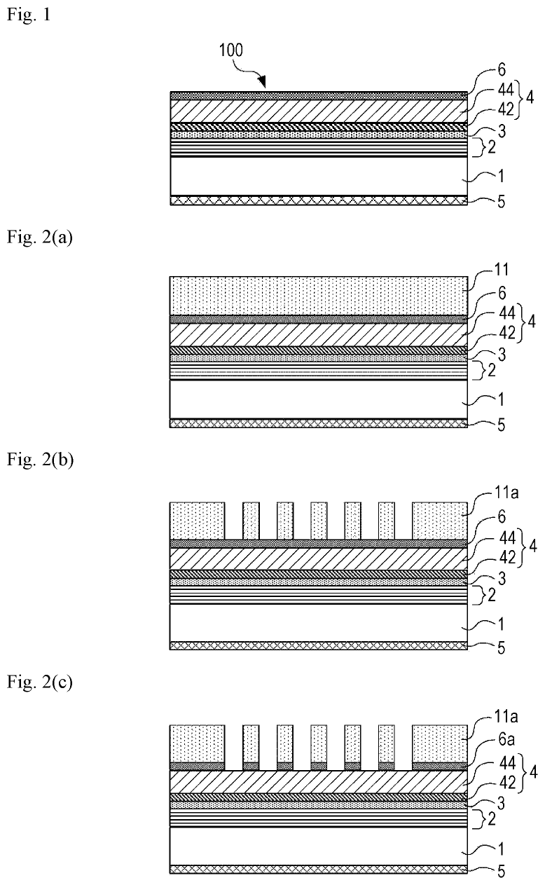

FIG. 1 is a schematic cross-sectional diagram of a main part for describing a configuration of a reflective mask blank 100 of an embodiment of the present disclosure. As shown in the figure, the reflective mask blank 100 includes a substrate 1, a multilayer reflective film 2, a protective film 3, an absorber film 4, and an etching mask film 6 that are layered in this order, the multilayer reflective film 2 being formed on a side of a first main surface (front surface) and reflecting the EUV light that is exposure light, the protective film 3 being provided to protect the multilayer reflective film 2, and the absorber film 4 absorbing the EUV light. In the reflective mask blank 100 of the present embodiment, the absorber film 4 includes a buffer layer 42 and an absorption layer 44 that is provided on the buffer layer 42. In addition, a conductive back film 5 for an electrostatic chuck is formed on a side of a second main surface (a back surface) of the substrate 1.

Additionally, the reflective mask blank 100 includes a configuration in which the conductive back film 5 is not formed. Furthermore, the reflective mask blank 100 includes a configuration of a mask blank with a resist film in which a resist film 11 is formed on the etching mask film 6.

In the present specification, for example, the description of “the multilayer reflective film 2 formed on a main surface of the substrate 1” means that the multilayer reflective film 2 is arranged in contact with a surface of the substrate 1 and also means that another film is provided between the substrate 1 and the multilayer reflective film 2. The same applies to other films. Additionally, in the present specification, for example, the expression of “a film A is arranged in contact with the film B” means that the film A and the film B are arranged in direct contact with each other without another film interposed between the film A and the film B.

Individual components of the reflective mask blank 100 will be specifically described below.

<<Substrate 1>>

As the substrate 1, a substrate having a low thermal expansion coefficient in the range of 0±5 ppb/° C. is preferably used in order to prevent distortion of an absorber pattern 4a due to heat at the time of exposure to EUV light. As the material having a low thermal expansion coefficient in this range, for example, SiO₂—TiO₂-based glass and multicomponent glass ceramics can be used.

In view of obtaining at least pattern transfer accuracy and position accuracy, a first main surface on a side of the substrate 1 where a transfer pattern (constituted by the pattern obtained by patterning the absorber film 4 as described later) is formed, has been subjected to a surface treatment so that the first main surface has high flatness. In the case of EUV exposure, the flatness in an area of 132 mm×132 mm of the main surface on the side of the substrate 1 where the transfer pattern is formed, is preferably 0.1 μm or less, more preferably 0.05 μm or less, and particularly preferably 0.03 μm or less. In addition, the second main surface being opposite to the side on which the absorber film 4 is formed is a surface to be electrostatically chucked when the substrate is set on an exposure apparatus, and a flatness of the second main surface is preferably 0.1 μm or less, more preferably 0.05 μm or less, and particularly preferably 0.03 μm or less in an area of 142 mm×142 mm.

In addition, high surface smoothness of the substrate 1 is also an extremely important item. Surface roughness of the first main surface of the substrate 1, on which the absorber pattern 4a for transfer is formed, is preferably a root mean square roughness (RMS) of 0.1 nm or less. Note that the surface smoothness can be measured with an atomic force microscope.

Furthermore, the substrate 1 has preferably high rigidity in order to prevent deformation due to film stress of a film (such as the multilayer reflective film 2) formed on the substrate 1. In particular, the substrate 1 preferably has a high Young's modulus of 65 GPa or more.

<<Multilayer Reflective Film 2>>

The multilayer reflective film 2 imparts a function of reflecting EUV light in a reflective mask 200, and has a multilayer film configuration in which individual layers including, as main components, elements having different refractive indexes are periodically layered.

Generally, a multilayer film with alternately layering roughly 40 to 60 periods of a thin film (high refractive index layer) of a light element that is a high refractive index material or a compound of the light element and a thin film (low refractive index layer) of a heavy element that is a low refractive index material or a compound of the heavy element is used for the multilayer reflective film 2. The multilayer film may be formed by building up the stack for a plurality of periods, as one period is a stack of a high refractive index layer and a low refractive index layer, and the high refractive index layer and the low refractive index layer are layered in this order from the substrate 1. Additionally, the multilayer film may be formed by building up the stack for a plurality of periods, as one is a stack of a low refractive index layer and a high refractive index layer, and the low refractive index layer and the high refractive index layer are layered in this order from the substrate 1. Note that a layer of the outermost surface of the multilayer reflective film 2, that is, a surface layer of the multilayer reflective film 2 on a side opposite to the substrate 1 is preferably a high refractive index layer. In a case building up the stack for a plurality of periods, as one period being a stack of a high refractive index layer and a low refractive index layer, and the high refractive index layer and the low refractive index layer being layered in this order from the substrate 1, the uppermost layer is a low refractive index layer. In this case, if the low refractive index layer constitutes the outermost surface of the multilayer reflective film 2, the low refractive index layer is easily oxidized and the reflectance of the reflective mask 200 is reduced. Thus, it is preferable to further form a high refractive index layer on the low refractive index layer that is the uppermost layer, in order to form the multilayer reflective film 2. Meanwhile, in a case building up the stack for a plurality of periods, as one period being a stack of a low refractive index layer and a high refractive index layer, and the low refractive index layer and the high refractive index layer being layered in this order from the substrate 1, the uppermost layer is a high refractive index layer and thus the stack may be as it is.

In the present embodiment, a layer including silicon (Si) is employed as the high refractive index layer. As a material including Si, a Si compound including boron (B), carbon (C), nitrogen (N), and oxygen (O) in Si may be used in addition to Si alone. By using the layer containing Si as the high refractive index layer, the reflective mask 200 for EUV lithography having an excellent EUV light reflectance can be obtained. In addition, in the present embodiment, a glass substrate is preferably used as the substrate 1. Si also has excellent adhesion to the glass substrate. In addition, as the low refractive index layer, a metal alone selected from molybdenum (Mo), ruthenium (Ru), rhodium (Rh), and platinum (Pt), or an alloy thereof is used. For example, as the multilayer reflective film 2 for EUV light having a wavelength of 13 nm to 14 nm, a Mo/Si periodic film stack in which a Mo film and a Si film are alternately layered for about 40 to 60 periods is preferably used. Note that a high refractive index layer that is the uppermost layer of the multilayer reflective film 2 may be formed using silicon (Si), and a silicon oxide layer containing silicon and oxygen may be formed between the uppermost layer (Si) and the Ru-based protective film 3. Thus, mask cleaning resistance can be improved.

The reflectance of such a multilayer reflective film 2 alone is usually 65% or more, and an upper limit is usually 73%. Note that the thickness and period of each constituent layer of the multilayer reflective film 2 are appropriately selected according to an exposure wavelength and are selected so as to satisfy the Bragg reflection law. In the multilayer reflective film 2, there are a plurality of high refractive index layers and a plurality of low refractive index layers. The thickness does not need to be the same between high refractive index layers and between low refractive index layers. Additionally, the film thickness of the Si layer that is the outermost surface of the multilayer reflective film 2 can be adjusted within a range that does not lower the reflectance. The film thickness of the Si (high refractive index layer) of the outermost surface can be 3 nm to 10 nm.

A method of forming the multilayer reflective film 2 is publicly known in this technical field. For example, the multilayer reflective film 2 can be formed by forming each layer in the multilayer reflective film 2 by an ion beam sputtering method. In the case of the above-mentioned Mo/Si periodic multilayer film, for example, a Si film having a thickness of about 4 nm is first formed on the substrate 1 using a Si target, for example, by the ion beam sputtering method. Then, a Mo film having a thickness of about 3 nm is formed using a Mo target. This formation is counted as one period and the Si film and the Mo film are stacked for 40 to 60 periods to form the multilayer reflective film 2 (the outermost layer is the Si layer). Additionally, when the multilayer reflective film 2 is formed, the multilayer reflective film 2 is preferably formed by supplying krypton (Kr) ion particles from an ion source and performing ion beam sputtering.

<<Protective Film 3>>

The reflective mask blank 100 of the present embodiment preferably has a protective film 3 between the multilayer reflective film 2 and the absorber film 4. The protective film 3 formed on the multilayer reflective film 2 enables to reduce damage to the surface of the multilayer reflective film 2 when the reflective mask 200 (EUV mask) is manufactured by using the reflective mask blank 100, and thus the reflectance characteristics with respect to EUV light are improved.

The protective film 3 is formed on the multilayer reflective film 2 in order to protect the multilayer reflective film 2 from dry etching and cleaning in a step of manufacturing the reflective mask 200 to be described later. Additionally, the protective film 3 also serves to protect the multilayer reflective film 2 when a black defect of the absorber pattern 4a is repaired using an electron beam (EB). The protective film 3 is formed of a material having resistance to an etchant, a cleaning liquid, and the like. Here, FIG. 1 shows a case where the protective film 3 is one layer, but the protective film 3 can include a stack of three or more layers. For example, the lowermost layer and the uppermost layer may be layers containing the substance containing Ru, and the protective film 3 may be one in which a metal or alloy other than Ru is interposed between the lowermost layer and the uppermost layer. A material of the protective film 3 includes, for example, a material including ruthenium as a main component. That is, the material of the protective film 3 may be a Ru metal alone or a Ru alloy containing Ru and at least one kind of a metal selected from titanium (Ti), niobium (Nb), molybdenum (Mo), zirconium (Zr), yttrium (Y), boron (B), lanthanum (La), cobalt (Co), rhenium (Re), and the like, and the material may contain nitrogen. The protective film 3 is particularly effective in a case where the buffer layer 42 included in the absorber film 4 is patterned by dry etching with a chlorine-based gas (Cl-based gas). The protective film 3 is preferably formed of a material having 1.5 or more, and preferably 3 or more of an etching selective ratio (etching rate of the absorber film 4/etching rate of the protective film 3) of the absorber film 4 to the protective film 3 in dry etching using a chlorine-based gas.

The Ru content of this Ru alloy is 50 atomic % or more and less than 100 atomic %, preferably 80 atomic % or more and less than 100 atomic %, and more preferably 95 atomic % or more and less than 100 atomic %. In particular, in a case where the Ru content of the Ru alloy is 95 atomic % or more and less than 100 atomic %, the EUV light reflectance can be secured sufficiently while the diffusion of the element (silicon) for forming the multilayer reflective film 2 to the protective film 3 is suppressed. Furthermore, this protective film 3 can have mask cleaning resistance, an etching stopper function when the absorber film 4 (specifically, the buffer layer 42) is etched, and a protective function for preventing the multilayer reflective film 2 from changing over time.

In EUV lithography, since there are few substances that are transparent to exposure light, it is not technically easy to achieve an EUV pellicle that prevents foreign matters from adhering to a mask pattern surface. For this reason, pellicle-less operation without using a pellicle has been the mainstream. Additionally, in the case of EUV lithography, exposure contamination such as carbon film deposition on a mask or an oxide film growth due to EUV exposure occurs. Thus, it is necessary to frequently clean and remove foreign matters and contamination on the EUV reflective mask 200 at a stage when the mask is used for manufacturing a semiconductor device. For this reason, the EUV reflective mask 200 is required to have extraordinary mask cleaning resistance compared with a transmissive mask for optical lithography. Using the Ru-based protective film 3 containing Ti provides particularly high cleaning resistance to cleaning liquids such as sulfuric acid, sulfuric acid peroxide (SPM), ammonia, ammonia peroxide (APM), hydroxyl (OH) radical cleaning water, and ozone water having a concentration of 10 ppm or less, thereby satisfying the requirement for mask cleaning resistance.

The thickness of the protective film 3 containing such Ru or an alloy thereof is not particularly limited as long as it can function as the protective film 3. The thickness of the protective film 3 is preferably 1.0 nm to 8.0 nm, and more preferably 1.5 nm to 6.0 nm from the viewpoint of the reflectance of EUV light.

As a method of forming the protective film 3, it is possible to adopt a film forming method similar to a publicly known method without any particular limitation. Specific examples include a sputtering method and an ion beam sputtering method.

<<Absorber Film 4>>

In the reflective mask blank 100 of the present embodiment, the absorber film 4 that absorbs EUV light is formed on the multilayer reflective film 2 or the protective film 3. The absorber film 4 has a function of absorbing EUV light. The absorber film 4 of the present embodiment includes a buffer layer 42 and an absorption layer 44 provided on the buffer layer 42 (on the side opposite to the substrate 1). The reflective mask blank 100 of the present embodiment includes the absorber film 4 in which the buffer layer 42 made of a material containing tantalum (Ta) or silicon (Si) and the absorption layer 44 made of a material containing chromium (Cr) are included, and also includes the etching mask film 6 made of a predetermined material described later, whereby the resist film 11 and the absorber film 4 can be made thinner.

As described later, the absorption layer 44 included in the absorber film 4 of the present embodiment is made of a material containing Cr. In a case where a thin film containing Cr is disposed on the protective film 3 containing Ru as a main material while the thin film is in contact with a surface of the protective film 3, there arises a problem of an etching selective ratio being not high between the absorption layer 44 and the protective film 3. Therefore, the buffer layer 42 made of a predetermined material is disposed between the absorption layer 44 and the protective film 3 in the absorber film 4 of the present embodiment.

In order to obtain film thicknesses of the buffer layer 42 and the absorption layer 44 included in the absorber film 4 of the reflective mask blank 100 of the present embodiment, simulations were performed as shown in FIGS. 3 to 6. As long as the reflectance of the absorber film 4 in EUV light is 2% or less, the absorber film 4 can be used as the reflective mask 200 for lithography for semiconductor device.

The structure used for the simulations shown in FIGS. 3 to 6 is a structure in which the multilayer reflective film 2 of Mo/Si periodic films and the protective film 3 (film thickness: 3.5 nm) made of ruthenium as a material are formed on the substrate 1, and the buffer layer 42 (film thickness: d2) and the absorption layer 44 (film thickness: d1) are further formed thereon. The multilayer reflective film 2 of the Mo-Si periodic films had a structure in which the film thickness of the Si layer is 4.2 nm and the film thickness of the Mo layer is 2.8 nm, the layers are built up on the substrate 1 for 40 periods where a single Si layer and a single Mo layer are counted as one period, and the Si layer having a thickness of 4.0 nm is disposed as the uppermost layer. The film thickness of the absorber film 4 (absorption layer 44/buffer layer 42) is denoted as D (=d1+d2). Note that the etching mask film 6 was not disposed in the structure because the simulations were intended to study a relationship between the reflectance of the absorber film 4 and the film thicknesses of the buffer layer 42 and the absorption layer 44 when the reflective mask 200 is manufactured. It is because the etching mask film 6 is finally removed when the reflective mask 200 is manufactured.

FIG. 3 shows a relationship between the film thickness D (=d1+d2, nm) of the absorber film 4 and the EUV light reflectance (%) on a surface of the absorber film 4, where d1 is the film thickness of the absorption layer 44 (material: CrN), d2 is the film thickness of the buffer layer 42 (material: TaBN), and the film thickness d2 of the buffer layer 42 is varied in the range of 2 to 20 nm. As shown in FIG. 3, the reflectance shows an oscillatory behavior with respect to a change in the film thickness D due to the interference of the EUV light with the film thickness D. Furthermore, as is clear from FIG. 3, in the case of the absorber film 4 including the CrN absorption layer 44 and the TaBN buffer layer 42, it can be understood that a local minimum value in the range of 2% or less of the EUV light reflectance occurs around 47 nm of the absorber film 4 and a local minimum value in the range of 1% or less of the reflectance occurs around 55 nm. In the case of the structure shown in FIG. 3, it can be understood that, in order to obtain the EUV light reflectance of 2% or less, the absorber film 4 needs to have a film thickness D of at least about 46 nm or more.

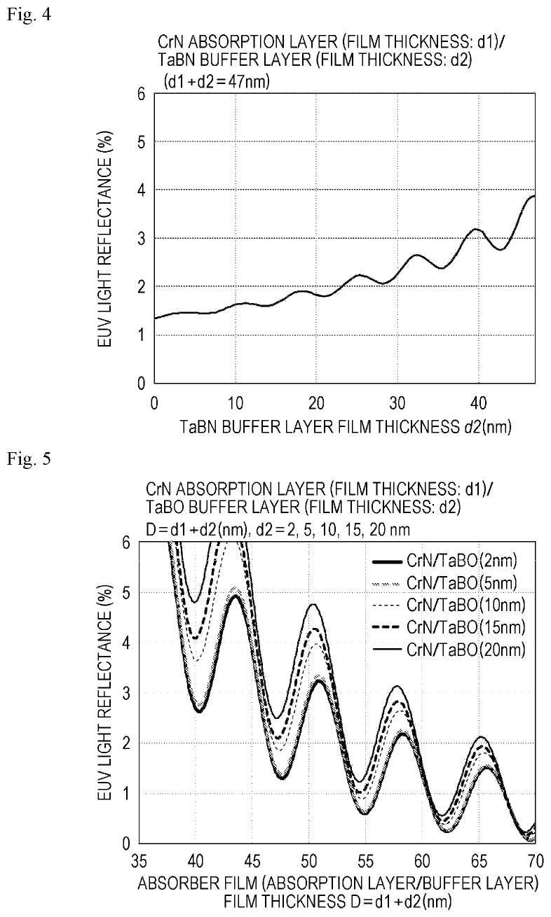

With reference to FIG. 3, a local minimum value in the range of 2% or less of the reflectance occurs around 47 nm of the absorber film 4. Therefore, the case of the absorber film 4 having a film thickness of 47 nm is further studied below. FIG. 4 shows the EUV light reflectance (%) on a surface of the absorber film 4, when the film thickness D (=d1+d2) of the absorber film 4 is 47 nm, and the film thickness d2 of the buffer layer 42 (material: TaBN) is varied from 0 to 47 nm. Note that the film thickness d1 of the absorption layer 44 (material: CrN) varies from 47 to 0 nm as the film thickness d2 of the buffer layer 42 is varied. As shown in FIG. 4, it can be understood that, in a case where the film thickness D (=d1+d2) of the absorber film 4 is set to 47 nm, the EUV light reflectance is 2% or less when the film thickness d2 of the buffer layer 42 (material: TaBN) falls in a range around 0 to 24 nm (when the film thickness d2 is approximately 0 to 25 nm). Therefore, when the film thickness d2 of the TaBN buffer layer 42 is 25 nm or less, the requirement of the EUV light reflectance, which is 2% or less, can be satisfied.

FIG. 5 shows a relationship between the film thickness D (nm) of the absorber film 4 and the EUV light reflectance (%) on a surface of the absorber film 4 in a case similar to the case in FIG. 3 except that the material of the buffer layer 42 is TaBO. Specifically, FIG. 5 shows a relationship between the film thickness D (=d1+d2, nm) of the absorber film 4 and the EUV light reflectance (%) on a surface of the absorber film 4, where d1 is the film thickness of the absorption layer 44 (material: CrN), d2 is the film thickness of the buffer layer 42 (material: TaBO), and the film thickness d2 of the buffer layer 42 is varied in the range of 2 to 20 nm. As in FIG. 3, FIG. 5 shows that the reflectance shows an oscillatory behavior with respect to a change in the film thickness D due to the interference of the EUV light with the film thickness D.

Furthermore, as is clear from FIG. 5, in the case of the absorber film 4 including the CrN absorption layer 44 and the TaBO buffer layer 42, it can be understood that a local minimum value in the range of 2% or less of the EUV light reflectance occurs around 47 nm of the absorber film 4 and a local minimum value in the range of 1% or less of the reflectance occurs around 55 nm. In the case of the structure shown in FIG. 5, it can be understood that, in order to obtain the EUV light reflectance of 2% or less, the absorber film 4 needs to have a film thickness D of at least about 46 nm or more when the film thickness of the TaBO buffer layer is 10 nm or less.

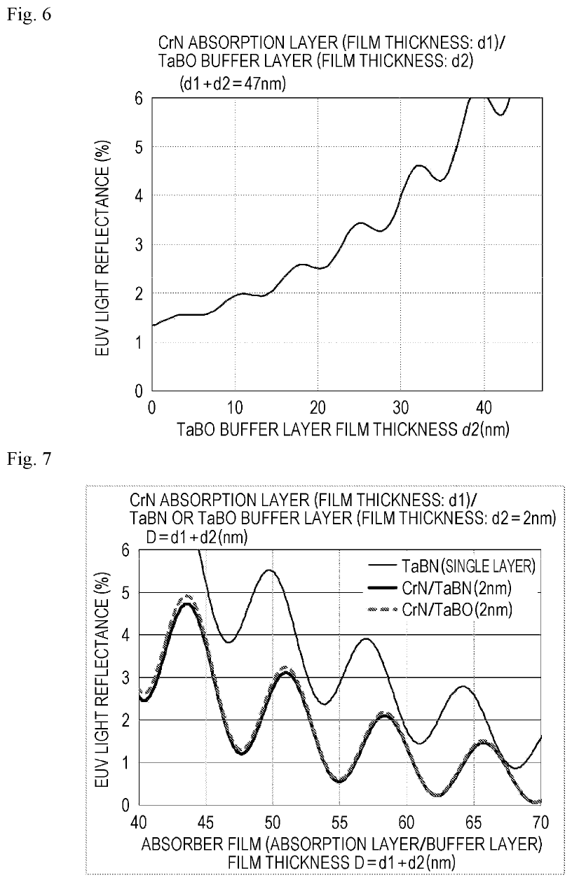

With reference to FIG. 5, a local minimum value in the range of 2% or less of the reflectance occurs around 47 nm of the absorber film 4. Therefore, as with the case in FIG. 4, the case of the absorber film 4 having a film thickness of 47 nm is further studied below. Similar to FIG. 4, FIG. 6 shows the EUV light reflectance (%) on a surface of the absorber film 4, when the film thickness D (=d1+d2) of the absorber film 4 is 47 nm, and the film thickness d2 of the buffer layer 42 (material: TaBO) is varied from 0 to 47 nm. Note that the film thickness d1 of the absorption layer 44 (material: CrN) varies from 47 to 0 nm as the film thickness d2 of the buffer layer 42 is varied. As shown in FIG. 6, it can be understood that, in a case where the film thickness D (=d1+d2) of the absorber film 4 is set to 47 nm, the EUV light reflectance is 2% or less when the film thickness d2 of the buffer layer 42 (material: TaBO) falls in a range around 0 to 14 nm (approximately around 0 to 15 nm). Therefore, when the film thickness d2 of the TaBO buffer layer 42 is 15 nm or less, the requirement of the EUV light reflectance, which is 2% or less, can be satisfied.

FIG. 7 shows a relationship between the film thickness D (=d1+d2) of the absorber film 4 (absorption layer 44/buffer layer 42) and the EUV light reflectance (%) on a surface of the absorber film 4, which is obtained through simulation. The structure used for the simulation is a structure in which the multilayer reflective film 2 of Mo/Si periodic films and the protective film 3 (3.5 nm) with a material of ruthenium are formed on the substrate 1, and the buffer layer 42 (film thickness: d2=2 nm) and the absorption layer 44 (film thickness: d1) are further formed thereon. Note that the multilayer reflective film 2 of Mo/Si periodic films had a structure similar to the structure used for the simulations in FIGS. 3 to 6 described above. The material of the buffer layer 42 was TaBN or TaBO. For reference, a relationship between the film thickness D of the absorber film 4 made of a single layer of a TaBN film without the buffer layer 42, which represents a conventional structure, and the EUV light reflectance (%) on a surface of the absorber film 4 is shown. It can be seen from FIG. 7 that the absorber film 4 including the CrN absorption layer 44 (absorption layer 44/buffer layer 42) has a greatly reduced EUV light reflectance (%) as compared with the conventional absorber film 4 made of the single TaBN film layer. Therefore, it can be understood that a reflectance of 2% or less can be achieved by using the absorber film 4 of the present embodiment even when the absorber film 4 is thinner than conventional absorber films.

In addition, in order to function as the buffer layer 42, the buffer layer 42 needs to have a film thickness of 0.5 nm or more. Therefore, in a case where the buffer layer 42 in the reflective mask blank 100 of the present embodiment is made of a material containing tantalum (Ta), it can be said that the buffer layer 42 needs to have a film thickness falling in the range from 0.5 nm to 25 nm in order to achieve a reflectance of 2% or less.

The foregoing description states that, from results of the simulations above, a reflectance of 2% or less can be achieved by using TaBN or TaBO as a material of the buffer layer 42 as long as the film thickness thereof falls within a predetermined range, even when the absorber film 4 is thinner than conventional absorber films. A similar simulation was performed by using a material containing silicon (Si) as the material of the buffer layer 42, and similar results were obtained.

That is, a result was obtained that, by simulations similar to those described above, the buffer layer 42 needs to have a film thickness in the range from 0.5 nm to 17 nm in order to achieve a reflectance of 2% or less in a case where the buffer layer 42 is made of a material containing silicon (Si) in the reflective mask blank 100 of the present embodiment. In addition, in a case where the buffer layer 42 is made of a material containing silicon (Si), the absorber film 4 needs to have a film thickness D of at least 46 nm in order to obtain an EUV light reflectance of 2% or less.

Next, the following further describes the case where the buffer layer 42 is made of a material containing tantalum (Ta).

In the reflective mask blank 100 of the present embodiment, the material of the buffer layer 42 preferably contains tantalum (Ta) and one or more elements selected from oxygen (O), nitrogen (N), carbon (C), boron (B), and hydrogen (H). More preferably, the material of the buffer layer 42 contains tantalum (Ta) and one or more elements selected from oxygen (O), nitrogen (N), boron (B), and hydrogen (H). As is clear from results of the simulations above, a reflectance of 2% or less can be achieved by using a predetermined tantalum (Ta)-based material as the material of the buffer layer 42, even when the absorber film 4 is thinner than conventional absorber films.

In addition, since a material containing tantalum (Ta) is used as the material of the buffer layer 42, an etching gas that does not substantially etch the buffer layer 42 can be selected for etching the absorption layer 44 that is made of a material containing chromium (Cr).

In the reflective mask blank 100 of the present embodiment, it is preferable that the material of the buffer layer 42 contains tantalum (Ta) and at least one element selected from nitrogen (N) and boron (B), and a film thickness of the buffer layer 42 is 25 nm or less. In addition, as shown in FIG. 4, when the film thickness of the buffer layer 42 is smaller, the EUV light reflectance can be lowered and the oscillation with respect to the film thickness can be reduced. Therefore, the film thickness of the buffer layer 42 is more preferably 15 nm or less, still more preferably 10 nm or less, and particularly preferably less than 4 nm. The material of the buffer layer 42 may contain tantalum (Ta) and nitrogen (N) and may not contain boron (B). Alternatively, the material of the buffer layer 42 may contain tantalum (Ta) and boron (B) and may not contain nitrogen (N). Using a material containing tantalum (Ta) and at least one element selected from nitrogen (N) and boron (B) as the material of the buffer layer 42 enables to avoid a problem of an etching selective ratio between the protective film 3 and the absorption layer 44, and a suitable etching gas can be selected, even when the absorption layer 44 is made of a material containing chromium (Cr). Furthermore, since it is possible to reduce the film thickness of the absorber film 4, the shadowing effect of the reflective mask 200 can be further reduced.

The content of tantalum in the buffer layer 42 is preferably 50 atomic % or more, and more preferably 70 atomic % or more. The content of tantalum in the buffer layer 42 is preferably 95 atomic % or less. The total content of nitrogen and boron in the buffer layer 42 is preferably 50 atomic % or less, and more preferably 30 atomic % or less. The total content of nitrogen and boron in the buffer layer 42 is preferably 5 atomic % or more. The content of nitrogen is preferably smaller than the content of boron. This is because, as the content of nitrogen is smaller, etching with a chlorine gas is faster and removal of the buffer layer 42 is easier. The content of hydrogen in the buffer layer 42 is preferably 0.1 atomic % or more, preferably 5 atomic % or less, and more preferably 3 atomic % or less.

The buffer layer 42 of the present embodiment made of a material containing tantalum (Ta) and at least one element selected from nitrogen (N) and boron (B) can be etched with a fluorine-based gas or a chlorine-based gas not containing oxygen.

As the fluorine-based gas, CF₄, CHF₃, C₂F₆, C₃F₆, C₄F₆, C₄F₈, CH₂F₂, CH₃F, C₃F₈, SF₆, F₂, and the like can be used. As the chlorine-based gas, Cl₂, SiCl₄, CHCl₃, CCl₄, BCl₃, and the like can be used. In addition, these etching gases can further include an inert gas such as He and/or Ar, if necessary.

In the reflective mask blank 100 of the present embodiment, the buffer layer 42 is preferably made of a material containing tantalum (Ta) and oxygen (O), and a film thickness of the buffer layer 42 is preferably 15 nm or less. In addition, as shown in FIG. 6, when the film thickness of the buffer layer 42 is smaller, the EUV light reflectance can be lowered and the oscillation with respect to the film thickness can be reduced. Therefore, the film thickness of the buffer layer 42 is more preferably 10 nm or less, and still more preferably less than 4 nm. Note that the material of the buffer layer 42 may contain boron (B) and/or hydrogen (H) in addition to tantalum (Ta) and oxygen (O). Using a material containing tantalum (Ta) and oxygen (O) as the material of the buffer layer 42 enables to avoid a problem of an etching selective ratio between the protective film 3 and the absorption layer 44, and a suitable etching gas can be selected, even when the absorption layer 44 is made of a material containing chromium (Cr). Furthermore, since it is possible to reduce the film thickness of the absorber film 4, the shadowing effect of the reflective mask 200 can be further reduced.

The content of tantalum in the buffer layer 42 is preferably 50 atomic % or more, and more preferably 70 atomic % or more. The content of tantalum in the buffer layer 42 is preferably 95 atomic % or less. The content of oxygen in the buffer layer 42 is preferably 70 atomic % or less, and more preferably 60 atomic % or less. The content of nitrogen in the buffer layer 42 is preferably 10 atomic % or more from the viewpoint of ease of etching. The content of hydrogen in the buffer layer 42 is preferably 0.1 atomic % or more, preferably 5 atomic % or less, and more preferably 3 atomic % or less.

The buffer layer 42 of the present embodiment made of a material containing tantalum (Ta) and oxygen (O) can be etched with an above-mentioned fluorine-based gas.

Next, the following describes the case where the buffer layer 42 is made of a material containing silicon.

In the reflective mask blank 100 of the present embodiment, the buffer layer 42 is preferably made of a material that contains silicon, a silicon compound, metal silicon including silicon and a metal, or a metal silicon compound including a silicon compound and a metal, and the material of a silicon compound preferably includes silicon and at least one element selected from oxygen (O), nitrogen (N), carbon (C), and hydrogen (H). In addition, the material containing a silicon compound, among the materials of the etching mask film 6, more preferably includes silicon and at least one element selected from oxygen (O) and nitrogen (N).

Specific examples of a material including silicon include SiO, SiN, SiON, SiC, SiCO, SiCN, SiCON, MoSi, MoSiO, MoSiN, MoSiON and the like. It is preferable to use SiO, SiN, or SiON as the material containing silicon. Note that the material can contain a metalloid or metal other than silicon to the extent that the effects of the present disclosure can be obtained. As the metal silicon compound, molybdenum silicide can be used.

As with the case of the buffer layer 42 made of a tantalum-based material described above, the buffer layer 42 made of a silicon-based material also enables to avoid a problem of an etching selective ratio between the protective film 3 and the absorption layer 44, and the film thickness of the absorber film 4 can be reduced. Therefore, the shadowing effect of the reflective mask 200 can be further reduced.

The buffer layer 42 is preferably formed of the same material as the material of the etching mask film 6 described later. As a result, the etching mask film 6 can be removed simultaneously when the buffer layer 42 is patterned. In addition, the buffer layer 42 and the etching mask film 6 may be formed of the same material and may have different composition ratios. Alternatively, the buffer layer 42 may be formed of a material containing tantalum, and the etching mask film 6 may be formed of a material containing silicon. Alternatively, the buffer layer 42 may be formed of a material containing silicon, and the etching mask film 6 may be formed of a material containing tantalum.

The film thickness of the buffer layer 42 is 0.5 nm or more, preferably 1 nm or more, and more preferably 2 nm or more from the viewpoint of preventing change of optical characteristics due to damaging to the protective film 3 when the absorber film 4 is etched. The film thickness of the buffer layer 42 is preferably 25 nm or less, more preferably 15 nm or less, still more preferably 10 nm or less, and particularly preferably less than 4 nm from the viewpoint of reducing the total film thickness of the absorber film 4 and the buffer layer 42, that is, reducing the height of the absorber pattern 4a.

The extinction coefficient of the buffer layer 42 may be 0.01 or more and less than 0.035.

Additionally, in a case where the buffer layer 42 and the etching mask film 6 are etched at the same time, the film thickness of the buffer layer 42 is preferably the same as, or smaller than, the film thickness of the etching mask film 6. Furthermore, in a case where (film thickness of the buffer layer 42)≤(film thickness of the etching mask film 6) holds, the relationship of (etching rate of the buffer layer 42)≤(etching rate of the etching mask film 6) is preferably satisfied.

The buffer layer 42 made of a material containing silicon can be etched with a fluorine-based gas.

Next, the following describes the absorption layer 44 included in the absorber film 4 of the present embodiment.

In the reflective mask blank 100 of an embodiment, EUV light is absorbed mainly in the absorption layer 44. For this reason, the absorption layer 44 is made of a material containing chromium (Cr), which has a relatively high extinction coefficient. Therefore, the material of the absorption layer 44 has a higher extinction coefficient for EUV light than the material of the buffer layer 42. The absorption layer 44 preferably has an extinction coefficient of 0.035 or more.

The absorption layer 44 is preferably made of a material containing chromium (Cr) and at least one element selected from nitrogen (N) and carbon (C). Note that the material of the absorption layer 44 may contain components of, for example, oxygen (O) and/or hydrogen (H) and the like, other than chromium (Cr), nitrogen (N), and carbon (C), to the extent that the extinction coefficient k is not adversely affected. The absorption layer 44 having a higher extinction coefficient k than a material containing tantalum (Ta) can be obtained by forming the absorption layer 44 with a predetermined material containing chromium (Cr) that has a high extinction coefficient k. Therefore, since it is possible to reduce the film thickness of the absorber film 4, the shadowing effect of the reflective mask 200 can be further reduced.

The material of the absorption layer 44 is a chromium compound containing chromium (Cr) and at least one element selected from nitrogen (N) and carbon (C). Examples of the chromium compound include CrN, CrC, CrON, CrCO, CrCN, CrCON, CrBN, CrBC, CrBON, CrBCN, CrBOCN, and the like. In order to increase the extinction coefficient of the absorption layer 44, the material preferably does not contain oxygen. In this case, it is also possible to increase the etching selective ratio with respect to a chlorine-based gas. Examples of the chromium compound that does not contain oxygen include CrN, CrC, CrCN, CrBN, CrBC, CrBCN, and the like. The Cr content of the chromium compound is preferably 50 atomic % or more and less than 100 atomic %, and more preferably 80 atomic % or more and less than 100 atomic %. The content of nitrogen (N) in a chromium compound is preferably 5 atomic % or more, preferably 20 atomic % or less, and more preferably 15 atomic % or less. Additionally, the expression of “not contain oxygen” herein corresponds to a chromium compound having an oxygen content of 10 atomic % or less, and preferably 5 atomic % or less. Note that the material can contain a metal other than chromium to the extent that the effects of the present disclosure can be obtained.

In the reflective mask blank 100 of the present embodiment, the absorption layer 44 is preferably made of a material containing chromium (Cr) and nitrogen (N), and a film thickness of the absorption layer 44 is preferably 25 nm or more and less than 60 nm. More preferably, the upper limit of the film thickness of the absorption layer 44 is less than 50 nm. More preferably, the lower limit of the film thickness of the absorption layer 44 is 35 nm or more, and still more preferably 45 nm or more. Since the film thickness of the absorption layer 44 can be set to an above-mentioned thickness by using a material containing chromium (Cr) and nitrogen (N) as the material of the absorption layer 44, the absorber film 4 can be thinner than conventional absorber films. Therefore, the shadowing effect of the reflective mask 200 can be further reduced.

The absorption layer 44 of the present embodiment made of a material containing chromium (Cr) can be etched with a mixed gas of an above-mentioned chlorine-based gas and an oxygen gas.

In the case of the absorber film 4 intended to absorb EUV light, the film thickness thereof is set so that the reflectance of EUV light to the absorber film 4 is 2% or less, and preferably 1% or less. Additionally, the film thickness of the absorber film 4 is required to be less than 60 nm, and more preferably 50 nm or less in order to reduce the shadowing effect.

Additionally, an oxide layer may be formed on the surface of the absorber film 4 (absorption layer 44). The cleaning resistance of the absorber pattern 4a of the obtained reflective mask 200 can be improved when the oxide layer is formed on the surface of the absorber film 4 (absorption layer 44). The thickness of the oxide layer is preferably 1.0 nm or more, and more preferably 1.5 nm or more. Additionally, the thickness of the oxide layer is preferably 5 nm or less, and more preferably 3 nm or less. If the thickness of the oxide layer is less than 1.0 nm, effects are unlikely to be exerted.

If the thickness of the oxide layer exceeds 5 nm, influence on the surface reflectance with respect to mask inspection light becomes large, and it becomes difficult to perform control for obtaining predetermined surface reflectance.

A method of forming the oxide layer includes subjecting the mask blank after the absorber film 4 (absorption layer 44) is formed to hot water treatment, ozone water treatment, heat treatment in an oxygen-containing gas, ultraviolet irradiation treatment in an oxygen-containing gas, and O₂ plasma treatment, and the like. Additionally, in a case where the surface of the absorber film 4 (absorption layer 44) is exposed to the atmosphere after the absorber film 4 (absorption layer 44) is formed, an oxide layer due to natural oxidation may be formed on a surface layer. In particular, in some cases, an oxide layer having a film thickness of 1 to 2 nm is formed.

<<Etching Mask Film 6>>

The etching mask film 6 in the reflective mask blank 100 of the present embodiment is made of a material containing tantalum (Ta) or silicon (Si). The film thickness of the etching mask film 6 is 0.5 nm or more and 14 nm or less.

With an appropriate etching mask film 6, the reflective mask blank 100 that enables to further reduce the shadowing effect of the reflective mask 200 and form a fine and highly accurate absorber pattern can be obtained.

As illustrated in FIG. 1, the etching mask film 6 is formed on the absorber film 4. As a material of the etching mask film 6, a material having a high etching selective ratio of the absorption layer 44 to the etching mask film 6 is used. Here, the expression of “an etching selective ratio of B to A” means a ratio of an etching rate of A that is a layer that is not desired to be etched (layer to serve as a mask) to an etching rate of B that is a layer that is desired to be etched. Specifically, “an etching selective ratio of B to A” is specified by the formula of “an etching selective ratio of B to A=an etching rate of B/an etching rate of A”. Additionally, the expression of “high selective ratio” means that a value of the selective ratio defined above is large as compared with that of an object for comparison. The etching selective ratio of the absorption layer 44 to the etching mask film 6 is preferably 1.5 or more, and more preferably 3 or more.

In the reflective mask blank 100 of the present embodiment, the material of the etching mask film 6 preferably contains tantalum (Ta) and one or more elements selected from oxygen (O), nitrogen (N), carbon (C), boron (B), and hydrogen (H). More preferably, the material of the etching mask film 6 contains tantalum (Ta) and one or more elements selected from oxygen (O), nitrogen (N), boron (B), and hydrogen (H). Since a predetermined material containing tantalum (Ta) is used as the material of the etching mask film 6, the etching mask film 6 with resistance to an etching gas for the absorption layer 44 made of a material containing chromium (Cr) can be formed.

The content of tantalum in the etching mask film 6 is preferably 50 atomic % or more, and more preferably 70 atomic % or more. The content of tantalum in the etching mask film 6 is preferably 95 atomic % or less. The content of oxygen in the etching mask film 6 is preferably 70 atomic % or less, and more preferably 60 atomic % or less. The content of nitrogen in the etching mask film 6 is preferably 10 atomic % or more from the viewpoint of ease of etching. The content of hydrogen in the etching mask film 6 is preferably 0.1 atomic % or more, preferably 5 atomic % or less, and more preferably 3 atomic % or less.

In the reflective mask blank 100 of the present embodiment, the material of the etching mask film 6 preferably contains tantalum (Ta) and one or more elements selected from nitrogen (N), carbon (C), boron (B), and hydrogen (H) and does not contain oxygen (O). More preferably, the material of the etching mask film 6 contains tantalum (Ta) and one or more elements selected from nitrogen (N), boron (B), and hydrogen (H) and does not contain oxygen (O). Since a predetermined material containing tantalum (Ta) but not containing oxygen (O) is used as the material of the etching mask film 6, the etching mask film 6 with more stable quality can be obtained. Note that the expression of “not contain oxygen” corresponds to a tantalum compound having an oxygen content of 10 atomic % or less, and preferably 5 atomic % or less.

The content of tantalum in the etching mask film 6 is preferably 50 atomic % or more, and more preferably 70 atomic % or more. The content of tantalum in the etching mask film 6 is preferably 95 atomic % or less. The total content of nitrogen and boron in the etching mask film 6 is preferably 50 atomic % or less, and more preferably 30 atomic % or less. The total content of nitrogen and boron in the etching mask film 6 is preferably 5 atomic % or more. The content of nitrogen is preferably smaller than the content of boron. This is because, as the content of nitrogen is smaller, etching with a chlorine gas is faster and removal of the etching mask film 6 is easier. The content of hydrogen in the etching mask film 6 is preferably 0.1 atomic % or more, preferably 5 atomic % or less, and more preferably 3 atomic % or less.

Note that oxygen (O) may be included in a portion (surface layer) around the surface of the etching mask film 6. During formation of the etching mask film 6, even when a material not containing oxygen (O) is used, the surface layer of the etching mask film 6 may include oxygen derived from a natural oxide film. During formation of the etching mask film 6, it is preferable to use a material not containing oxygen (O). Since the etching mask film 6 except its surface layer does not contain oxygen (O), the etching mask film 6 having more stable quality can be obtained.

The etching mask film 6 of the present embodiment made of a material containing tantalum (Ta) can be etched with an above-mentioned fluorine-based gas or a chlorine-based gas not containing oxygen. Additionally, the etching mask film 6 of the present embodiment made of a material containing tantalum (Ta) but not containing oxygen can be etched with an above-mentioned chlorine-based gas not containing oxygen.

The etching mask film 6 of the present embodiment can be made of a material containing silicon. The material containing silicon is preferably a material that contains silicon, a silicon compound, metal silicon including silicon and a metal, or a metal silicon compound including a silicon compound and a metal, where the material containing a silicon compound preferably includes silicon and at least one element selected from oxygen (O), nitrogen (N), carbon (C), and hydrogen (H). In addition, the material containing a silicon compound, among the materials of the etching mask film 6, more preferably includes silicon and at least one element selected from oxygen (O) and nitrogen (N). Since a predetermined material containing silicon (Si) is used as the material of the etching mask film 6, the etching mask film 6 with resistance to an etching gas for the absorption layer 44 made of a material containing chromium (Cr) can be formed.

Specific examples of a material including silicon include SiO, SiN, SiON, SiC, SiCO, SiCN, SiCON, MoSi, MoSiO, MoSiN, MoSiON and the like. It is preferable to use SiO, SiN, or SiON as the material containing silicon. Note that the material can contain a metalloid or metal other than silicon to the extent that the effects of the present disclosure can be obtained. As the metal silicon compound, molybdenum silicide can be used.

The etching mask film 6 made of a material containing silicon can be etched with a fluorine-based gas.

From the viewpoint of obtaining a function as an etching mask for accurately forming a transfer pattern on the absorber film 4, the film thickness of the etching mask film 6 is 0.5 nm or more, preferably 1 nm or more, more preferably 2 nm or more, and still more preferably 3 nm or more. Additionally, from the viewpoint of reducing the film thickness of the resist film 11, the film thickness of the etching mask film 6 is 14 nm or less, preferably 12 nm or less, and more preferably 10 nm or less.

The etching mask film 6 and the buffer layer 42 may be made of the same material. Alternatively, the etching mask film 6 and the buffer layer 42 may be made of materials containing the same metal with different composition ratios. In the case where the etching mask film 6 and the buffer layer 42 contain tantalum, the content of tantalum in the etching mask film 6 may be greater than the content of tantalum in the buffer layer 42, and the film thickness of the etching mask film 6 may be larger than the film thickness of the buffer layer 42. In the case where the etching mask film 6 and the buffer layer 42 contain hydrogen, the content of hydrogen in the etching mask film 6 may be greater than the content of hydrogen in the buffer layer 42.

<<Resist Film 11>>

The reflective mask blank 100 of the present embodiment may have a resist film 11 on the etching mask film 6. The reflective mask blank 100 of the present embodiment includes a mode in which the resist film 11 is included. In the reflective mask blank 100 of the present embodiment, the resist film 11 can be thinner by selecting the absorber film 4 (buffer layer 42 and absorption layer 44) having an appropriate material and/or an appropriate film thickness, and selecting an appropriate etching gas.

As a material of the resist film 11, for example, a chemically-amplified resist (CAR) can be used. The reflective mask 200 having a predetermined transfer pattern can be manufactured by patterning the resist film 11 and etching the absorber film 4 (buffer layer 42 and absorption layer 44).

<<Conductive Back Film 5>>

The conductive back film 5 for an electrostatic chuck is generally formed on the side of the second main surface (back surface) of the substrate 1 (side opposite to a forming face of the multilayer reflective film 2). An electrical characteristic (sheet resistance) required of the conductive back film 5 for an electrostatic chuck is usually 100 Ω/□ (Ω/square) or less. The conductive back film 5 can be formed by, for example, a magnetron sputtering method or an ion beam sputtering method using a target of a metal such as chromium or tantalum or an alloy thereof

A material including chromium (Cr) for the conductive back film 5 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN and the like.

As a material including tantalum (Ta) for the conductive back film 5, it is preferable to use Ta (tantalum), an alloy containing Ta, or a Ta compound containing either of Ta or the alloy containing Ta and at least one from boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON and the like.

As a material including tantalum (Ta) or chromium (Cr), an amount of nitrogen (N) present in the surface layer thereof is preferably small. Specifically, it is preferable that nitrogen content in the surface layer of the conductive back film 5 of the material including tantalum (Ta) or chromium (Cr) is less than 5 atomic %, and it is more preferable that the surface layer substantially contains no nitrogen. This is because, in the conductive back film 5 of the material including tantalum (Ta) or chromium (Cr), the lower the nitrogen content in the surface layer is, the higher wear resistance is.

The conductive back film 5 preferably includes a material including tantalum and boron. When the conductive back film 5 includes the material including tantalum and boron, a conductive film 23 having wear resistance and chemical resistance can be obtained. In a case where the conductive back film 5 includes tantalum (Ta) and boron (B), B content is preferably 5 to 30 atomic %. The ratio of Ta to B (Ta:B) in a sputtering target used for forming the conductive back film 5 is preferably from 95:5 to 70:30.

The thickness of the conductive back film 5 is not particularly limited as long as a function as being for an electrostatic chuck is fulfilled. The thickness of the conductive back film 5 is usually 10 nm to 200 nm. In addition, the conductive back film 5 further has a function of stress adjustment on the side of the second main surface of the mask blank 100. That is, the conductive back film 5 is adjusted so that the flat reflective mask blank 100 can be obtained in balance with the stress from various films formed on the side of the first main surface.

<Reflective Mask 200 and Method of Manufacturing the Same>

The reflective mask 200 of the present embodiment includes the absorber pattern 4a in which the absorber film 4 in the above-described reflective mask blank 100 is patterned.

The absorber pattern 4a of the reflective mask 200 is capable of absorbing EUV light and reflecting the EUV light at the openings of the absorber pattern 4a. Therefore, a predetermined fine transfer pattern can be transferred to a transferred object by irradiating EUV light to the reflective mask 200 using a predetermined optical system.

The reflective mask 200 is manufactured using the reflective mask blank 100 of the present embodiment. Here, an outline description will be only given, and a detailed description will be given later in Examples with reference to the drawings.

The reflective mask blank 100 is prepared. The resist film 11 is formed on the etching mask film 6 that is formed on the absorber film 4 on the first main surface of the reflective mask blank 100 (this is not necessary in a case where the resist film 11 is provided as the reflective mask blank 100). A desired pattern is drawn (exposed) on the resist film 11 and further developed and rinsed, whereby a predetermined resist pattern 11a is formed.

In the case of the reflective mask blank 100, the resist pattern 11a is used as a mask to etch the etching mask film 6, thereby forming the etching mask pattern 6a. The resist pattern 11a is peeled off by oxygen ashing or wet treatment with hot sulfuric acid or the like. Next, the etching mask pattern 6a is used as a mask to etch the absorption layer 44, thereby forming the absorption layer pattern 44a. Next, the exposed etching mask pattern 6a and absorption layer pattern 44a are used as a mask to etch the buffer layer 42, thereby forming the buffer layer pattern 42a. The etching mask pattern 6a is removed to form the absorber pattern 4a that includes the absorption layer pattern 44a and the buffer layer pattern 42a. Finally, wet cleaning is performed using an acidic or alkaline aqueous solution.

Note that the etching mask pattern 6a can be removed by simultaneously etching the etching mask pattern 6a and the buffer layer 42 during patterning of the buffer layer 42.

In the reflective mask 200 of the present embodiment, the etching mask pattern 6a may be left on the absorber pattern 4a without being removed. In this case, however, the etching mask pattern 6a needs to remain as a uniform thin film. From the viewpoint of avoiding non-uniformity as a thin film of the etching mask pattern 6a, it is preferable not to provide but to remove the etching mask pattern 6a in the reflective mask 200 of the present embodiment.

In a method of manufacturing the reflective mask 200 of the present embodiment, the etching mask film 6 of the above-described reflective mask blank 100 of the present embodiment is preferably patterned with a dry etching gas including a fluorine-based gas. In the case of the etching mask film 6 containing tantalum (Ta), the etching mask film 6 can be suitably dry-etched with a fluorine-based gas. In addition, the absorption layer 44 is preferably patterned with a dry etching gas containing a chlorine-based gas and an oxygen gas. The absorption layer made of a material containing chromium (Cr) can be suitably dry-etched with a dry etching gas containing a chlorine-based gas and an oxygen gas. In addition, the buffer layer 42 is preferably patterned with a dry etching gas containing a chlorine-based gas. In the case of the buffer layer 42 containing tantalum (Ta), the buffer layer 42 can be suitably dry-etched with a dry etching gas containing a chlorine-based gas. In this way, the absorber pattern 4a of the reflective mask 200 can be formed.

Through the above steps, the reflective mask 200 having a small shadowing effect and a highly accurate and fine pattern can be obtained.

<Method of Manufacturing Semiconductor Device>

A method of manufacturing a semiconductor device of the present embodiment includes a step of setting the reflective mask 200 of the present embodiment in an exposure apparatus having an exposure light source that emits EUV light and transferring a transfer pattern to a resist film formed on a transferred substrate.

According to the method of manufacturing a semiconductor device of the present embodiment, the reflective mask 200 that enables to reduce the film thickness of the absorber film 4, reduce the shadowing effect, and form the fine and highly accurate absorber film 4 can be used for manufacturing a semiconductor device. Thus, a semiconductor device having a fine and highly accurate transfer pattern can be manufactured.

By performing EUV exposure using the above-described reflective mask 200 of the present embodiment, a desired transfer pattern based on an absorber pattern 4a on the reflective mask 200 can be formed on the semiconductor substrate while a decrease in accuracy of a transfer dimension due to a shadowing effect can be suppressed. In addition, since the absorber pattern 4a is a fine and highly accurate pattern with small sidewall roughness, a desired pattern can be formed on the semiconductor substrate with high dimensional accuracy. In addition to this lithography step, various steps such as etching of a film to be processed, formation of an insulating film and a conductive film, introduction of a dopant, or annealing are undergone, whereby it is possible to manufacture a semiconductor device on which a desired electronic circuit is formed.

More specifically, the EUV exposure apparatus includes a laser plasma light source that generates EUV light, an illumination optical system, a mask stage system, a reduction projection optical system, a wafer stage system, and vacuum equipment, and the like. The light source is provided with a debris trap function, a cut filter that cuts light having a long wavelength other than exposure light, equipment for vacuum differential pumping, and the like. The illumination optical system and the reduction projection optical system each include a reflection mirror. The reflective mask 200 for EUV exposure is electrostatically absorbed by the conductive film formed on the second main surface of the reflective mask 200 and is mounted on the mask stage.

The light of the EUV light source is applied to the reflective mask 200 through the illumination optical system at an angle tilted by 6° to 8° with respect to a vertical plane of the reflective mask 200. Reflected light from the reflective mask 200 with respect to this incident light is reflected (regularly reflected) in a direction opposite to an incident direction and at the same angle as an incident angle, guided to a reflective projection system usually having a reduction ratio of ¼, and exposed on a resist on a wafer (semiconductor substrate) mounted on a wafer stage. During this time, at least a place through which EUV light passes is evacuated. Additionally, when this exposure is performed, mainstream exposure is scan exposure in which the mask stage and the wafer stage are synchronously scanned at a speed corresponding to the reduction ratio of the reduction projection optical system, and exposure is performed through a slit. Then, the resist film that has been subjected to the exposure is developed, whereby a resist pattern can be formed on the semiconductor substrate. In the present disclosure, the mask having the highly accurate absorber pattern 4a that is a thin film and has a small shadowing effect and small sidewall roughness is used. Therefore, the resist pattern formed on the semiconductor substrate is desired one with high dimensional accuracy. Then, etching or the like is performed using this resist pattern as a mask, whereby a predetermined wiring pattern can be formed, for example, on the semiconductor substrate. The semiconductor device is manufactured through such an exposure step, a step of processing a film to be processed, a step of forming an insulating film and a conductive film, a dopant introduction step, an annealing step, and other necessary steps.

### EXAMPLES

Hereinafter, Examples will be described with reference to the drawings. Note that in Examples, the same reference signs are used for similar constituent elements, and the description thereof is simplified or omitted.

### Example 1

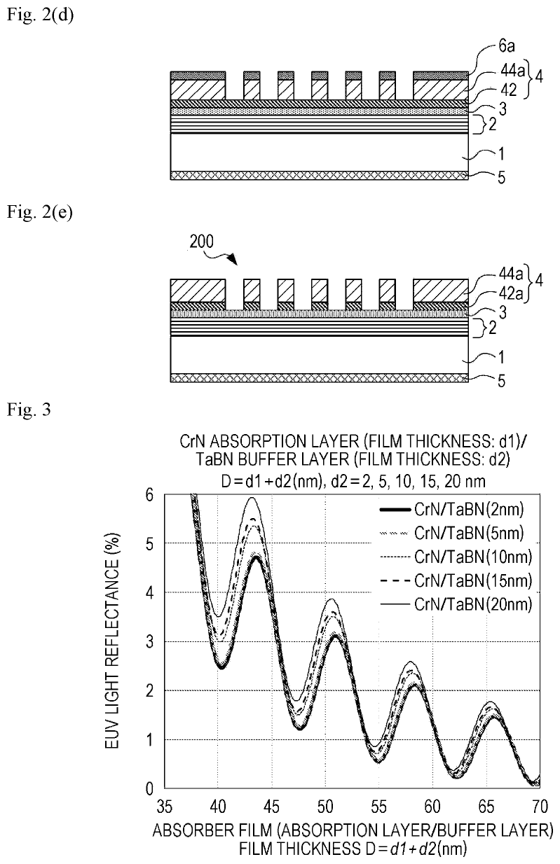

As illustrated in FIG. 1, the reflective mask blank 100 of Example 1 includes the conductive back film 5, the substrate 1, the multilayer reflective film 2, the protective film 3, the absorber film 4, and the etching mask film 6. The absorber film 4 includes the buffer layer 42 and the absorption layer 44. Then, as shown in FIG. 2(a), the resist film 11 is formed on the absorber film 4. FIGS. 2(a) to 2(e) are each a schematic cross-sectional diagram of a main part showing steps of manufacturing the reflective mask 200 from the reflective mask blank 100.

The elemental composition of the deposited thin film described below was measured by Rutherford backscattering spectrometry.

First, the reflective mask blank 100 of Example 1 (Examples 1-1 to 1-5) is described.

A SiO₂—TiO₂-based glass substrate that is a low thermal expansion glass substrate having 6025 size (approximately 152 mm×152 mm×6.35 mm) and having polished both main surfaces that are a first main surface and a second main surface was prepared as the substrate 1. The main surfaces were subjected to polishing including a rough polishing step, a precision polishing step, a local processing step, and a touch polishing step so that the main surfaces were flat and smooth.

Next, the conductive back film 5 including a CrN film was formed on the second main surface (a back surface) of the SiO₂—TiO₂-based glass substrate (the substrate 1) by a magnetron sputtering (a reactive sputtering) method under the following conditions.

Conditions for forming the conductive back film 5: a Cr target, a mixed gas atmosphere of Ar and N₂ (Ar: 90%, N: 10%), and a film thickness of 20 nm.

Next, the multilayer reflective film 2 was formed on the main surface (first main surface) of the substrate 1 on a side opposite to the side on which the conductive back film 5 was formed. The multilayer reflective film 2 formed on the substrate 1 was a periodic multilayer reflective film 2 including Mo and Si in order to make the multilayer reflective film 2 suitable for EUV light having a wavelength of 13.5 nm. The multilayer reflective film 2 was formed using a Mo target and a Si target and alternately layering a Mo layer and a Si layer on the substrate 1 by an ion beam sputtering method in an Ar gas atmosphere. First, a Si film was formed with a thickness of 4.2 nm, and then a Mo film was formed with a thickness of 2.8 nm. This formation was counted as one period, and the Si film and the Mo film were layered for 40 periods in a similar manner. Finally, a Si film was formed with a thickness of 4.0 nm to form the multilayer reflective film 2. The number of periods was 40 periods here, but the number of periods is not limited to this number and may be, for example, 60 periods. In the case of 60 periods, the number of steps is larger than the number of steps in the case of 40 periods, but reflectance for EUV light can be increased.

Subsequently, the protective film 3 including a Ru film was formed to have a film thickness of 3.5 nm using a Ru target in an Ar gas atmosphere by an ion beam sputtering method.

Next, the absorber film 4 including the buffer layer 42 and the absorption layer 44 was formed on the protective film 3. Table 1 shows materials, extinction coefficients, material composition ratios, etching gases, and film thicknesses of the protective film 3, the buffer layer 42, the absorption layer 44, and the etching mask film 6 of Example 1.

Specifically, first, the buffer layer 42 including a TaBN film was formed by a DC magnetron sputtering method. The TaBN film was formed with a film thickness of 2 to 20 nm using a TaB mixed sintering target by reactive sputtering in a mixed gas atmosphere of an Ar gas and a N₂ gas, as shown in Table 1.

As shown in Table 1, the element ratio of the TaBN film in Examples 1-1 to 1-5 w as 75 atomic % of Ta, 12 atomic % of B, and 13 atomic % of N. As shown in Table 1, the extinction coefficient k of the TaBN film (buffer layer 42) at a wavelength of 13.5 nm was 0.030.

Next, the absorption layer 44 including a CrN film was formed by a magnetron sputtering method. The CrN film was formed with a film thickness of 27 to 46 nm using a Cr target by reactive sputtering in a mixed gas atmosphere of an Ar gas and a N₂ gas, as shown in Table 1.

As shown in Table 1, the elemental ratio of the CrN film in Examples 1-1 to 1-5 was 90 atomic % of Cr and 10 atomic % of N. As shown in Table 1, the extinction coefficient k of the CrN film (absorption layer 44) at a wavelength of 13.5 nm was 0.038.

Next, the etching mask film 6 including a TaBO film was formed on the absorption layer 44 by a direct current (DC) magnetron sputtering method. The TaBO film was formed with a film thickness of 6 nm using a TaB target by reactive sputtering in a mixed gas atmosphere of an Ar gas and an O₂ gas, as shown in Table 1.

As shown in Table 1, the element ratio of the TaBO film in Examples 1-1 to 1-5 was 41 atomic % of Ta, 6 atomic % of B, and 53 atomic % of O.

In this way, the reflective mask blanks 100 of Examples 1-1 to 1-5 were produced.

Next, using the reflective mask blanks 100 of Examples 1-1 to 1-5 described above, the reflective mask 200 of Example 1 was produced.

The resist film 11 was formed with a thickness of 80 nm on the etching mask film 6 of the reflective mask blank 100 (FIG. 2(a)). A chemically-amplified resist (CAR) was used to form the resist film 11. A desired pattern was drawn (exposed) on the resist film 11, and further developed and rinsed to form a predetermined resist pattern 11a (FIG. 2(b)). Next, using the resist pattern 11a as a mask, the TaBO film (the etching mask film 6) was dry-etched using a mixed gas of a CF₄ gas and a He gas (CF₄+He gas). As a result, the etching mask pattern 6a was formed (FIG. 2(c)). The resist pattern 11a was peeled off by oxygen ashing. Using the etching mask pattern 6a as a mask, the CrN film (the absorption layer 44) was dry-etched with a mixed gas of a Cl₂ gas and an O₂ gas (Cl₂+O₂ gas). As a result, the absorption layer pattern 44a was formed (FIG. 2(d)).

After that, the buffer layer 42 was patterned by dry etching with a Cl₂ gas. A TaO-based thin film is highly resistant to dry etching with a chlorine-based gas, and the etching mask films 6 of Examples 1-1 to 1-5 were each a TaBO film (TaO-based thin film). Therefore, the 6 nm etching mask film 6 had sufficient etching resistance when the buffer layer 42 was dry-etched with a Cl₂ gas. After that, the etching mask pattern 6a was removed by a mixed gas of a CF₄ gas and a He gas (FIG. 2(e)). Finally, wet cleaning was performed with deionized water (DIW) to produce the reflective masks 200 of Examples 1-1 to 1-5.

Note that a mask defect inspection can be performed as necessary after the wet cleaning, and a mask defect can be corrected appropriately.

The EUV light reflectance of the absorber pattern 4a at a wavelength of 13.5 nm was measured on the reflective masks 200 of Examples 1-1 to 1-5 produced as described above. The “EUV light reflectance” field in Table 1 shows EUV light reflectances in Examples 1-1 to 1-5.

In the reflective masks 200 of Examples 1-1 to 1-5, the film thickness of the absorber pattern 4a including the buffer layer 42 and the absorption layer 44 was 47 to 48 nm, which means the absorber pattern 4a was made thinner than the absorber film 4 formed of a conventional Ta-based material, and the shadowing effect was reduced. In addition, the EUV light reflectance of each of the absorber films 4 of Examples 1-1 to 1-5 was 2% or less.

The reflective masks 200 produced in Examples 1-1 to 1-5 were each set in an EUV exposure scanner, and EUV exposure was performed on a wafer on which a film to be processed and a resist film were formed on a semiconductor substrate. Then, the resist film that has been subjected to the exposure was developed, whereby a resist pattern was formed on the semiconductor substrate on which the film to be processed was formed.

Additionally, this resist pattern was transferred on the film to be processed by etching, and a semiconductor device having desired characteristics was manufactured through various steps such as formation of an insulating film and a conductive film, introduction of a dopant, and annealing.

### Example 2 (Examples 2-1 to 2-3) and Reference Example 1 (Reference Examples 1-1 and 1-2)

Table 2 shows materials, extinction coefficients, material composition ratios, etching gases, and film thicknesses of the protective film 3, the buffer layer 42, the absorption layer 44, and the etching mask film 6 of Example 2 and Reference Example 1. Example 2 and Reference Example 1 represent examples in which the buffer layer 42 was a TaBO film and the etching mask film 6 was a TaBN film, and were basically similar to Example 1 except that the film thicknesses were as shown in Table 2. The TaBO film of the buffer layer 42 was formed in a similar manner to the TaBO film of the etching mask film 6 in Example 1. As shown in Table 2, the extinction coefficient k of the TaBO film (buffer layer 42) at a wavelength of 13.5 nm was 0.023. The TaBN film of the etching mask film 6 was formed in a similar manner to the TaBN film of the buffer layer 42 in Example 1.

Next, using the reflective mask blanks 100 of Example 2 and Reference Example 1 described above, the reflective masks 200 of Example 2 and Reference Example 1 were produced in the same manner as in Example 1. Table 2 shows types of etching gases used for etching the buffer layer 42, the absorption layer 44, and the etching mask film 6 during production of the reflective masks 200 of Example 2 and Reference Example 1. Note that a TaN-based thin film can be etched by dry etching with a fluorine-based gas. Since the etching mask films 6 of Example 2 and Reference Example 1 were each a TaBN film (a TaN-based thin film), the etching mask film 6 was simultaneously etched with dry etching of the buffer layer 42 with a mixed gas of a CF₄ gas and a He gas. For this reason, in Example 2 and Reference Example 1, the etching mask film 6 had a greater film thickness than the buffer layer 42 as shown in Table 2.

The EUV light reflectance of the absorber pattern 4a at a wavelength of 13.5 nm was measured on the reflective masks 200 of Examples 2-1 to 2-3 and Reference Examples 1-1 and 1-2 produced as described above. The “EUV light reflectance” field in Table 2 shows EUV light reflectances in Examples 2-1 to 2-3 and Reference Examples 1-1 and 1-2.

As shown in Table 2, EUV light reflectances were 2% or less in Examples 2-1 to 2-3. In contrast, EUV light reflectances in Reference Examples 1-1 and 1-2 exceeded 2%. Regarding Reference Examples 1-1 and 1-2, it is conceivable that the reflectances were higher because the absorption layer 44, which had a higher extinction coefficient, had a film thickness of 32 nm or less, and thus could not absorb the EUV light sufficiently in the absorption layer 44. In a case where the buffer layer 42 is made of a material having an extinction coefficient of 0.025 or less as in Example 2 and Reference Example 1, it is believed that the absorption layer 44 needs a thickness of at least 35 nm.

In the reflective masks 200 of Examples 2-1 to 2-3, the film thickness of the absorber pattern 4a including the buffer layer 42 and the absorption layer 44 was 47 to 48 nm, which means the absorber pattern 4a was made thinner than the absorber film 4 formed of a conventional Ta-based material, and the shadowing effect was reduced.

The reflective masks 200 produced in Examples 2-1 to 2-3 were each set in an EUV exposure scanner, and EUV exposure was performed on a wafer on which a film to be processed and a resist film were formed on a semiconductor substrate. Then, the resist film that has been subjected to the exposure was developed, whereby a resist pattern was formed on the semiconductor substrate on which the film to be processed was formed.

Additionally, this resist pattern was transferred on the film to be processed by etching, and a semiconductor device having desired characteristics was manufactured through various steps such as formation of an insulating film and a conductive film, introduction of a dopant, and annealing.

### Example 3

Table 3 shows materials, extinction coefficients, material composition ratios, etching gases, and film thicknesses of the protective film 3, the buffer layer 42, the absorption layer 44, and the etching mask film 6 of Example 3. Example 3 represents an example in which the buffer layer 42 was a TaBO film, and was basically similar to Example 1 except that the film thicknesses were as shown in Table 3. The TaBO film of the buffer layer 42 was formed in a similar manner to the TaBO film of the etching mask film 6 in Example 1.

Next, using the reflective mask blank 100 of Example 3 described above, the reflective mask 200 of Example 3 was produced in the same manner as in Example 1. Table 3 shows types of etching gases used for etching the buffer layer 42, the absorption layer 44, and the etching mask film 6 during production of the reflective mask 200 of Example 3. In Example 3, the buffer layer 42 was patterned and at the same time the etching mask pattern 6a was removed.

The EUV light reflectance of the absorber pattern 4a at a wavelength of 13.5 nm was measured on the reflective mask 200 of Example 3 produced as described above. The “EUV light reflectance” field in Table 3 shows an EUV light reflectance in Example 3.

As shown in Table 3, the EUV light reflectance in Example 3 was 1.4%, that is, 2% or less.

In the reflective mask 200 of Example 3, the film thickness of the absorber pattern 4a including the buffer layer 42 and the absorption layer 44 was 48 nm, which means the absorber pattern 4a was made thinner than the absorber film 4 formed of a conventional Ta-based material, and the shadowing effect was reduced.

The reflective mask 200 produced in Example 3 was set in an EUV exposure scanner, and EUV exposure was performed on a wafer on which a film to be processed and a resist film were formed on a semiconductor substrate. Then, the resist film that has been subjected to the exposure was developed, whereby a resist pattern was formed on the semiconductor substrate on which the film to be processed was formed.

Additionally, this resist pattern was transferred on the film to be processed by etching, and a semiconductor device having desired characteristics was manufactured through various steps such as formation of an insulating film and a conductive film, introduction of a dopant, and annealing.

### Example 4 (Examples 4-1 to 4-4)

Table 4 shows materials, extinction coefficients, material composition ratios, etching gases, and film thicknesses of the protective film 3, the buffer layer 42, the absorption layer 44, and the etching mask film 6 of Example 4 (Examples 4-1 to 4-4). Example 4 represents an example in which the etching mask film 6 was a TaBN film, and was basically similar to Example 1 except that the film thicknesses were as shown in Table 4. The TaBN film of the etching mask film 6 was formed in a similar manner to the TaBN film of the buffer layer 42 in Example 1.

Next, using the reflective mask blank 100 of Example 4 described above, the reflective mask 200 of Example 4 was produced in the same manner as in Example 1. Table 4 shows types of etching gases used for etching the buffer layer 42, the absorption layer 44, and the etching mask film 6 during production of the reflective mask 200 of Example 4. As shown in Table 4, in Example 4, etching gases being different among Examples 4-1 to 4-4 were used for etching the etching mask film 6 (TaBN film). Note that the resist film 11 has high resistance to dry etching with a fluorine-based gas. Therefore, in cases where the etching mask film 6 is dry-etched with a fluorine-based gas as in Examples 4-2 to 4-4, the film thickness of the resist film 11 can be reduced. Specifically, the film thickness of the resist film 11, which is about 80 nm in Example 4-1, can be reduced to 30 to 50 nm, and therefore a finer pattern can be formed.

The EUV light reflectance of the absorber pattern 4a at a wavelength of 13.5 nm was measured on the reflective mask 200 of Example 4 produced as described above. The “EUV light reflectance” field in Table 4 shows an EUV light reflectance in Example 4.

As shown in Table 4, every EUV light reflectance in Example 4 was 0.6%, that is, 2% or less.

In the reflective mask 200 of Example 4, the film thickness of the absorber pattern 4a including the buffer layer 42 and the absorption layer 44 was 55 nm, which means the absorber pattern 4a was made thinner than the absorber film 4 formed of a conventional Ta-based material, and the shadowing effect was reduced.

The reflective mask 200 produced in Example 4 was set in an EUV exposure scanner, and EUV exposure was performed on a wafer on which a film to be processed and a resist film were formed on a semiconductor substrate. Then, the resist film that has been subjected to the exposure was developed, whereby a resist pattern was formed on the semiconductor substrate on which the film to be processed was formed.

Additionally, this resist pattern was transferred on the film to be processed by etching, and a semiconductor device having desired characteristics was manufactured through various steps such as formation of an insulating film and a conductive film, introduction of a dopant, and annealing.

### Example 5

Table 5 shows materials, extinction coefficients, material composition ratios, etching gases, and film thicknesses of the protective film 3, the buffer layer 42, the absorption layer 44, and the etching mask film 6 of Example 5. Example 5 represents an example in which the buffer layer 42 and the etching mask film 6 were each a SiO₂ film, and was basically similar to Example 1 except that the film thicknesses were as shown in Table 5. The SiO₂ films of the buffer layer 42 and the etching mask film 6 were formed as described below.

The SiO₂ films for forming the buffer layer 42 and the etching mask film 6 of Example 5 were formed by an RF magnetron sputtering method. Specifically, as shown in Table 5, the buffer layer 42 and the etching mask film 6 were formed to have film thicknesses of 3.5 nm and 6 nm, respectively, by using a SiO₂ target in an Ar gas atmosphere. The other films were formed as in Example 1.

Next, using the reflective mask blank 100 of Example 5 described above, the reflective mask 200 of Example 5 was produced in the same manner as in Example 1. Table 5 shows types of etching gases used for etching the buffer layer 42, the absorption layer 44, and the etching mask film 6 during production of the reflective mask 200 of Example 5.

The EUV light reflectance of the absorber pattern 4a at a wavelength of 13.5 nm was measured on the reflective mask 200 of Example 5 produced as described above. The “EUV light reflectance” field in Table 5 shows an EUV light reflectance in Example 5.

As shown in Table 5, the EUV light reflectance in Example 5 was 1.8%, that is, 2% or less.

In the reflective mask 200 of Example 5, the film thickness of the absorber pattern 4a including the buffer layer 42 and the absorption layer 44 was 47.5 nm, which means the absorber pattern 4a was made thinner than the absorber film 4 formed of a conventional Ta-based material, and the shadowing effect was reduced.

The reflective mask 200 produced in Example 5 was set in an EUV exposure scanner, and EUV exposure was performed on a wafer on which a film to be processed and a resist film were formed on a semiconductor substrate. Then, the resist film that has been subjected to the exposure was developed, whereby a resist pattern was formed on the semiconductor substrate on which the film to be processed was formed.

Additionally, this resist pattern was transferred on the film to be processed by etching, and a semiconductor device having desired characteristics was manufactured through various steps such as formation of an insulating film and a conductive film, introduction of a dopant, and annealing.

### Comparative Example 1

As Comparative Example 1, a mask blank was produced by using a conventional TaBN film for the absorber film 4. Table 6 shows materials, extinction coefficients, material composition ratios, etching gases, and film thicknesses of the protective film 3 and the absorber film 4 of Comparative Example 1. Comparative Example 1 was basically similar to Example 1 except that the absorber film 4 was a TaBN film (single layer film) and the etching mask film 6 was not formed. The TaBN film of the absorber film 4 was formed in a similar manner to the TaBN film of the buffer layer 42 in Example 1.

Next, using the reflective mask blank 100 of Comparative Example 1 described above, the reflective mask 200 of Comparative Example 1 was produced in the same manner as in Example 1. Table 6 shows a type of etching gas used for etching the absorber film 4 during production of the reflective mask 200 of Comparative Example 1.

The EUV light reflectance of the absorber pattern 4a at a wavelength of 13.5 nm was measured on the reflective mask 200 of Comparative Example 1 produced as described above. The “EUV light reflectance” field in Table 6 shows an EUV light reflectance in Comparative Example 1.

As shown in Table 6, the EUV light reflectance in Comparative Example 1 was 1.4%, that is, 2% or less.

In the reflective mask 200 of Comparative Example 1, the film thickness of the absorber pattern 4a made of a conventional Ta-based material was 62 nm, and the shadowing effect could not be reduced.

TABLE 1

| | | | | | Film thickness | | | | | | | | | |
|---|---|---|---|---|---|---|---|---|---|---|---|---|---|---|
| | | Extinction | | | | | | | | | | | | |
| | | coefficient | Material composition | Etching | Example | | Example | | Example | | Example | | Example | |
| Structure | Material | k | ratio (atomic %) | gas | 1-1 | | 1-2 | | 1-3 | | 1-4 | | 1-5 | |
| Resist film | CAR | — | — | — | 80 | nm | 80 | nm | 80 | nm | 80 | nm | 80 | nm |
| Etching mask | TaBO | — | Ta:B:O = 41:6:53 | CF₄ + He | 6 | nm | 6 | nm | 6 | nm | 6 | nm | 6 | nm |
| film | | | | | | | | | | | | | | |
| Absorption | CrN | 0.038 | Cr:N = 90:10 | Cl₂ + O₂ | 46 | nm | 43 | nm | 38 | nm | 32 | nm | 27 | nm |
| layer | | | | | | | | | | | | | | |
| Buffer layer | TaBN | 0.030 | Ta:B:N = 75:12:13 | Cl₂ | 2 | nm | 5 | nm | 10 | nm | 15 | nm | 20 | nm |
| Protective | Ru | — | — | — | 3.5 | nm | 3.5 | nm | 3.5 | nm | 3.5 | nm | 3.5 | nm |
| film | | | | | | | | | | | | | | |

| | | | | | |
|---|---|---|---|---|---|
| EUV light reflectance | 1.4% | 1.5% | 1.6% | 1.7% | 1.8% |

TABLE 2

| | | | | | Film thickness | | | | | | | | | |
|---|---|---|---|---|---|---|---|---|---|---|---|---|---|---|
| | | Extinction | Material | | | | | | | | Reference | | Reference | |
| | | coefficient | composition ratio | Etching | Example | | Example | | Example | | Example | | Example | |
| Structure | Material | k | (atomic %) | gas | 2-1 | | 2-2 | | 2-3 | | 1-1 | | 1-2 | |
| Resist film | CAR | — | — | — | 80 | nm | 80 | nm | 80 | nm | 80 | nm | 80 | nm |
| Etching mask | TaBN | — | Ta:B:N = 75:12:13 | CF₄ + He | 4 | nm | 7 | nm | 12 | nm | 17 | nm | 22 | nm |
| film | | | | | | | | | | | | | | |
| Absorption | CrN | 0.038 | Cr:N = 90:10 | Cl₂ + O₂ | 46 | nm | 43 | nm | 37 | nm | 32 | nm | 27 | nm |
| layer | | | | | | | | | | | | | | |
| Buffer layer | TaBO | 0.023 | Ta:B:O = 41:6:53 | CF₄ + He | 2 | nm | 5 | nm | 10 | nm | 15 | nm | 20 | nm |
| Protective | Ru | — | — | — | 3.5 | nm | 3.5 | nm | 3.5 | nm | 3.5 | nm | 3.5 | nm |
| film | | | | | | | | | | | | | | |

| | | | | | |
|---|---|---|---|---|---|
| EUV light reflectance | 1.4% | 1.5% | 1.9% | 2.2% | 2.4% |

TABLE 3

| | | Extinction | Material | | | |
|---|---|---|---|---|---|---|
| | | coefficient | composition ratio | Etching | Film thickness | |
| Structure | Material | k | (atomic %) | gas | Example 3 | |
| Resist film | CAR | — | — | — | 80 | nm |
| Etching mask film | TaBO | — | Ta:B:O = 41:6:53 | CF₄ + He | 6 | nm |
| Absorption layer | CrN | 0.038 | Cr:N = 90:10 | Cl₂ + O₂ | 46 | nm |
| Buffer layer | TaBO | 0.023 | Ta:B:O = 41:6:53 | CF₄ + He | 2 | nm |
| Protective film | Ru | — | — | — | 3.5 | nm |

| | |
|---|---|
| EUV light reflectance | 1.4% |

TABLE 4

| | | Extinction | Material | | | | | | | | | |
|---|---|---|---|---|---|---|---|---|---|---|---|---|
| | | coefficient | composition ratio | Etching | Film thickness, (etching gas) | | | | | | | |
| Structure | Material | k | (atomic %) | gas | Example 4-1 | | Example 4-2 | | Example 4-3 | | Example 4-4 | |
| Resist film | CAR | — | — | — | 80 | nm | 50 | nm | 40 | nm | 30 | nm |
| Etching mask | TaBN | — | Ta:B:N = 75:12:13 | See | 3 nm, (Cl₂) | | 3 nm, (SF₆ + He) | | 3 nm, (CF₄ + He) | | 3 nm, (CHF₃ + He) | |
| film | | | | right | | | | | | | | |
| | | | | columns | | | | | | | | |
| Absorption | CrN | 0.038 | Cr:N = 90:10 | Cl₂ + O₂ | 53 | nm | 53 | nm | 53 | nm | 53 | nm |
| layer | | | | | | | | | | | | |
| Buffer layer | TaBN | 0.030 | Ta:B:N = 75:12:13 | Cl₂ | 2 | nm | 2 | nm | 2 | nm | 2 | nm |
| Protective | Ru | — | — | — | 3.5 | nm | 3.5 | nm | 3.5 | nm | 3.5 | nm |
| film | | | | | | | | | | | | |

| | | | | |
|---|---|---|---|---|
| EUV light reflectance | 0.6% | 0.6% | 0.6% | 0.6% |

TABLE 5

| | | Extinction | Material | | | |
|---|---|---|---|---|---|---|
| | | coefficient | composition ratio | Etching | Film thickness | |
| Structure | Material | k | (atomic %) | gas | Example 5 | |
| Resist film | CAR | — | — | — | 80 | nm |
| Etching | SiO₂ | — | Si:O = 1:2 | CHF₃ + He | 6 | nm |
| mask film | | | | | | |
| Absorption | CrN | 0.038 | Cr:N = 90:10 | Cl₂ + O₂ | 44 | nm |
| layer | | | | | | |
| Buffer | SiO₂ | 0.012 | Si:O = 1:2 | | 3.5 | nm |
| layer | | | | | | |
| Protective | Ru | — | — | — | 3.5 | nm |
| film | | | | | | |

| | |
|---|---|
| EUV light reflectance | 1.6% |

TABLE 6

| | | Extinction | Material | | Film thickness | |
|---|---|---|---|---|---|---|
| | | coefficient | composition ratio | Etching | Comparative | |
| Structure | Material | k | (atomic %) | gas | Example 1 | |
| Resist film | CAR | — | — | — | 150 | nm |
| Absorber | TaBN | 0.038 | Ta:B:N = 75:12:13 | Cl₂ | 62 | nm |
| film | | | | | | |
| Protective | Ru | — | — | — | 3.5 | nm |
| film | | | | | | |

| | |
|---|---|
| EUV light reflectance | 1.4% |

### REFERENCE SIGNS LIST

1 Substrate

2 Multilayer reflective film

3 Protective film

4 Absorber film

4a Absorber pattern

5 Conductive back film

6 Etching mask film

6a Etching mask pattern

11 Resist film

11a Resist pattern

42 Buffer layer

42a Buffer layer pattern

44 Absorption layer

44a Absorption layer pattern

100 Reflective mask blank

200 Reflective mask

1. A reflective mask blank comprising:
a substrate,
a multilayer reflective film disposed on the substrate,
an absorber film disposed on the multilayer reflective film, and
an etching mask film disposed on the absorber film, wherein
the absorber film comprises a buffer layer and an absorption layer provided on the buffer layer,
the buffer layer comprises tantalum (Ta) or silicon (Si), and a film thickness of the buffer layer is 0.5 nm or more and 25 nm or less,
the absorption layer comprises chromium (Cr), and an extinction coefficient of the absorption layer with respect to EUV light is higher than the extinction coefficient of the buffer layer with respect to EUV light, and
the etching mask film comprises tantalum (Ta) or silicon (Si), and a film thickness of the etching mask film is 0.5 nm or more and 14 nm or less.

2. The reflective mask blank according to claim 1, wherein the buffer layer comprises tantalum (Ta) and one or more elements selected from oxygen (O), nitrogen (N) and boron (B).

3. The reflective mask blank according to claim 1, wherein the buffer layer comprises tantalum (Ta) and at least one element selected from nitrogen (N) and boron (B), and a film thickness of the buffer layer is 25 nm or less.

4. The reflective mask blank according to claim 1, wherein the buffer layer comprises tantalum (Ta) and oxygen (O), and a film thickness of the buffer layer is 15 nm or less.

5. The reflective mask blank according to claim 1, wherein the absorption layer comprises chromium (Cr) and at least one element selected from nitrogen (N) and carbon (C).

6. The reflective mask blank according to claim 1, wherein the absorption layer comprises chromium (Cr) and nitrogen (N), and a film thickness of the absorption layer is 25 nm or more and less than 60 nm.

7. The reflective mask blank according to claim 1, wherein the etching mask film comprises tantalum (Ta) and one or more elements selected from oxygen (O), nitrogen (N), and boron (B).

8. The reflective mask blank according to claim 1, wherein the etching mask film comprises tantalum (Ta) and one or more elements selected from nitrogen (N) and boron (B) and does not contain oxygen (O).

9. The reflective mask blank according to claim 1, wherein the etching mask film comprises silicon and at least one element selected from oxygen (O) and nitrogen (N).

10. The reflective mask blank according to claim 9, wherein the buffer layer comprises silicon and at least one element selected from oxygen (O) and nitrogen (N).

11. The reflective mask blank according to claim 1, wherein a protective film is provided between the multilayer reflective film and the absorber film.

12. The reflective mask blank according to claim 1, wherein a resist film is provided on the etching mask film.

13. A reflective mask comprising an absorber pattern in which the absorber film in the reflective mask blank according to claim 1 is patterned.

14. A method of manufacturing a reflective mask, the method comprising: patterning an etching mask film with a dry etching gas comprising a fluorine-based gas; patterning an absorption layer with a drying etching gas comprising a chlorine-based gas and an oxygen gas; and patterning a buffer layer with a dry etching gas comprising a fluorine-based gas to form an absorber pattern in a reflective mask blank, wherein
the reflective mask blank comprises a multilayer reflective film, an absorber film, and the etching mask film,
the absorber film comprises the buffer layer and the absorption layer provided on the buffer layer,
the buffer layer comprises tantalum (Ta) or silicon (Si) and a film thickness of the buffer layer is 0.5 nm or more and 25 nm or less,
the absorption layer comprises chromium (Cr) and an extinction coefficient of the absorption layer with respect to EUV light is higher than an extinction coefficient of the buffer layer with respect to EUV light, and
the etching mask film comprises tantalum (Ta) or silicon (Si) and a film thickness of the etching mask film is 0.5 nm or more and 14 nm or less.

15. A method of manufacturing a semiconductor device, the method comprising: setting the reflective mask according to claim 13 in an exposure apparatus having an exposure light source that emits EUV light and transferring a transfer pattern to a resist film formed on a transferred substrate.

16. The method of manufacturing a reflective mask according to claim 14, wherein the buffer layer comprises tantalum (Ta) and one or more elements selected from oxygen (O), nitrogen (N), and boron (B).

17. The method of manufacturing a reflective mask according to claim 14, wherein the buffer layer comprises tantalum (Ta) and oxygen (O), and a film thickness of the buffer layer is 15 nm or less.

18. The method of manufacturing a reflective mask according to claim 14, wherein the absorption layer comprises chromium (Cr) and at least one element selected from nitrogen (N) and carbon (C).

19. The method of manufacturing a reflective mask according to claim 14, wherein the absorption layer comprises chromium (Cr) and nitrogen (N), and a film thickness of the absorption layer is 25 nm or more and less than 60 nm.

20. The method of manufacturing a reflective mask according to claim 14, wherein the etching mask film comprises tantalum (Ta) and one or more elements selected from oxygen (O), nitrogen (N), and boron (B).

21. The method of manufacturing a reflective mask according to claim 14, wherein the etching mask film comprises silicon and at least one element selected from oxygen (O) and nitrogen (N).
